(19) United States
(12) Patent Application Publication
(10) Pub. No.: US 2009/0072343 A1
(43) Pub. Date: Mar. 19, 2009

(54) SEMICONDUCTOR DEVICE AND ELECTRONIC APPLIANCE

(75) Inventors: Hideto OHNUMA, Atsugi (JP); Yoichi IIKUBO, Tokyo (JP); Yoshiaki YAMAMOTO, Tokyo (JP); Kenichiro MAKINO, Atsugi (JP); Akihisa SHIMOMURA, Isehara (JP); Eiji HIGA, Atsugi (JP); Tatsuya MIZOI, Yokohama (JP); Yoji NAGANO, Atsugi (JP); Fumito ISAKA, Zama (JP); Tetsuya KAKEHATA, Isehara (JP); Shunpei YAMAZAKI, Tokyo (JP)

Correspondence Address: John F. Hayden;FISH & RICHARDSON P.C, 11th Floor, 1425 K Street, N.W, Washington, DC, 20005, US

(73) Assignee: SEMICONDUCTOR ENERGY LABORATORY CO., LTD., Atsugi-shi (JP)

(21) Appl. No.: 12/207,634

(22) Filed: Sep. 10, 2008

(30) Foreign Application Priority Data
Sep. 14, 2007 (JP) 2007-240219

(51) Int. Cl. H01L 29/00

(52) U.S. Cl. 257/506; 257/E29.001

(57) ABSTRACT

A high-performance semiconductor device using an SOI substrate in which a low-heat-resistance substrate is used as a base substrate. Further, a high-performance semiconductor device formed without using chemical polishing. Further, an electronic device using the semiconductor device. An insulating layer over an insulating substrate, a bonding layer over the insulating layer, and a single-crystal semiconductor layer over the bonding layer are included, and the arithmetic-mean roughness of roughness in an upper surface of the single-crystal semiconductor layer is greater than or equal to 1 nm and less than or equal to 7 nm. Alternatively, the root-mean-square roughness of the roughness may be greater than or equal to 1 nm and less than or equal to 10 nm. Alternatively, a maximum difference in height of the roughness may be greater than or equal to 5 nm and less than or equal to 250 nm.

### TECHNICAL FIELD

The present invention relates to a semiconductor device and an electronic appliance.

Note that a semiconductor device in this specification refers to all devices which can function by utilizing semiconductor characteristics, and electro-optical devices, semiconductor circuits, and electronic appliances are all included in the category of the semiconductor device.

### BACKGROUND ART

In recent years, instead of a bulk silicon wafer, integrated circuits using an SOI (silicon on insulator) substrate have been developed. By utilizing characteristics of a thin single-crystal-silicon layer formed over an insulating layer, transistors formed in the integrated circuit can be electrically separated from each other completely. Further, each transistor can be formed as a fully-depleted transistor, and thus a semiconductor integrated circuit with high added value such as high integration, high speed driving, and low power consumption can be realized.

As a method for manufacturing an SOI substrate, a hydrogen-ion-implantation separation method in which hydrogen ion implantation and separation are combined is known. A typical process of a hydrogen-ion-implantation separation method will be described below.

First, hydrogen ions are implanted into a silicon wafer to form an ion implantation layer at a predetermined depth from the surface. Next, a silicon oxide film is formed by oxidizing another silicon wafer which serves as a base substrate. After that, the silicon wafer into which hydrogen ions are implanted is bonded to the silicon oxide film of the another silicon wafer, so that the two silicon wafers are attached to each other. Then, heat treatment is performed so that the wafer is separated with the ion implantation layer as a separation plane. Note that heat treatment is performed in order to improve the bonding force in the attachment.

There is a known method in which a single-crystal-silicon layer is formed over a glass substrate by using a hydrogen-ion-implantation separation method (e.g., Reference 1: Japanese Published Patent Application No. Hei11-097379). In Reference 1, a separation plane is mechanically polished in order to remove a defect layer formed by ion implantation or a step which is several to several tens of nanometers in height in the separation plane.

### DISCLOSURE OF INVENTION

Glass substrates are larger in area and more inexpensive than silicon wafers, and are mainly used for manufacturing display devices such as a liquid crystal display device. By using a glass substrate as a base substrate, an inexpensive large-area SOI substrate can be manufactured.

However, the strain point of a glass substrate is equal to or lower than 700° C., and the heat resistance thereof is low. Therefore, heating cannot be performed at temperatures over the allowable temperature limit of the glass substrate and the process temperature is limited to 700° C. or below. That is, there is limitation of process temperature also in removing a crystal defect or surface roughness in the separation plane. Further, there is limitation of process temperature also in manufacturing a transistor with the use of a single-crystal-silicon layer attached to a glass substrate.

Further, since the size of a glass substrate is large, there is limitation of a usable apparatus or process method. For example, it is not realistic that the mechanical polishing of the separation plane described in Reference 1 is applied to a large-area substrate, in terms of processing accuracy, cost for an apparatus, or the like. However, to bring out characteristics of a semiconductor element, it is necessary that the surface roughness in the separation surface be suppressed to a certain degree.

As described above, in the case where a substrate which is large in area and low in heat resistance, such as a glass substrate, is used as a base substrate, it is difficult to suppress surface roughness of a semiconductor layer and to obtain desired characteristics.

In view of the forgoing problems, it is an object of the present invention to provide a high-performance semiconductor device using an SOI substrate in which a low-heat-resistance substrate is used as a base substrate. Further, it is an object of the present invention to provide a high-performance semiconductor device without performing mechanical polishing (e.g., CMP). Further, it is an object of the present invention to provide an electronic appliance using the semiconductor device.

According to one aspect of the present invention, a semiconductor device includes an insulating layer over an insulating substrate, a bonding layer over the insulating layer, and a single-crystal semiconductor layer over the bonding layer, and the arithmetic-mean roughness in an upper surface of the single-crystal semiconductor layer is greater than or equal to 1 nm and less than or equal to 7 nm.

According to another aspect of the present invention, a semiconductor device includes an insulating layer over an insulating substrate, a bonding layer over the insulating layer, and a single-crystal semiconductor layer over the bonding layer, and the root-mean-square roughness in an upper surface of the single-crystal semiconductor layer is greater than or equal to 1 nm and less than or equal to 10 nm.

According to another aspect of the present invention, a semiconductor device includes an insulating layer over an insulating substrate, a bonding layer over the insulating layer, and a single-crystal semiconductor layer over the bonding layer, and the maximum difference in height in an upper surface of the single-crystal semiconductor layer is greater than or equal to 5 nm and less than or equal to 250 nm.

According to another aspect of the present invention, a semiconductor device includes a substrate with an allowable temperature limit of 700° C. or less, an insulating layer over the substrate, a bonding layer over the insulating layer, and a single-crystal semiconductor layer over the bonding layer, and the arithmetic-mean roughness in an upper surface of the single-crystal semiconductor layer is greater than or equal to 1 nm and less than or equal to 7 nm.

According to another aspect of the present invention, a semiconductor device includes a substrate with an allowable temperature limit of 700° C. or less, an insulating layer over the substrate, a bonding layer over the insulating layer, and a single-crystal semiconductor layer over the bonding layer, and the root-mean-square roughness in an upper surface of the single-crystal semiconductor layer is greater than or equal to 1 nm and less than or equal to 10 nm.

According to another aspect of the present invention, a semiconductor device includes a substrate with an allowable temperature limit of 700° C. or less, an insulating layer over the substrate, a bonding layer over the insulating layer, and a single-crystal semiconductor layer over the bonding layer, and the maximum difference in height in an upper surface of the single-crystal semiconductor layer is greater than or equal to 5 nm and less than or equal to 250 nm.

In any of the above-described structures, the substrate is preferably a glass substrate including any of aluminosilicate glass, aluminoborosilicate glass, or bariumborosilicate glass. The size of the substrate is not particularly limited as long as it is the size to which application of a CMP process is difficult, for example, over 300 mm on each side.

Further, in any of the above-described structures, the bonding layer may include a silicon oxide film formed by chemical vapor deposition using an organosilane gas. Further, the insulating layer may include a silicon oxynitride film or a silicon nitride oxide film.

Further, in any of the above-described structures, the single-crystal semiconductor layer may have a (100) plane as a main surface (a surface on which integrated circuits are formed). Alternatively, the single-crystal semiconductor layer may have a (110) plane as a main surface.

Note that the upper surface of the single-crystal semiconductor layer is provided with smooth roughness by laser beam irradiation. That is, the convex shape in the upper surface is not sharply-peaked but is smooth with a given radius of curvature or more.

Note that treatment of thinning or planarization may be performed on the single-crystal semiconductor layer in order to control thickness of the single-crystal semiconductor layer or reduce the surface roughness. As the above-described treatment, one of dry etching or wet etching, or etching in which dry etching and wet etching are combined can be used. It is needless to say that an etch-back treatment may be performed. The treatment can be applied to either before or after laser beam irradiation.

Further, in any of the above-described structures, it is preferable that the average width of each concave or convex portion in the above-described roughness be greater than or equal to 60 nm and less than or equal to 120 nm. Note that the width of each concave or convex portion is measured with an average height.

Various electronic appliances can be provided using the above-described semiconductor device.

In the semiconductor device of the present invention, a substrate of which allowable temperature limit is low is used and the surface roughness of a single-crystal semiconductor layer is suppressed to a certain degree or less without performing mechanical polishing. Accordingly, a high-performance semiconductor device can be provided using an SOI substrate in which a low-heat-resistance substrate is used as a base substrate. Further, various electronic appliances can be provided using the semiconductor device.

### BRIEF DESCRIPTION OF DRAWINGS

FIGS. 1A to 1H are cross-sectional views of a method for manufacturing an SOI substrate.

FIGS. 2A to 2C are cross-sectional views of a method for manufacturing an SOI substrate and show a process which follows FIG. 1H.

FIGS. 3A to 3G are cross-sectional views of a method for manufacturing an SOI substrate.

FIGS. 4A to 4C are cross-sectional views of a method for manufacturing an SOI substrate and show a process which follows FIG. 3G.

FIGS. 5A to 5H are cross-sectional views of a method for manufacturing an SOI substrate.

FIGS. 6A to 6C are cross-sectional views of a method for manufacturing an SOI substrate and show a process which follows FIG. 5H.

FIGS. 7A to 7D are cross-sectional views of a method for manufacturing a semiconductor device using an SOI substrate.

FIGS. 8A and 8B are cross-sectional views of a method for manufacturing a semiconductor device using an SOI substrate and show a process which follows FIG. 7D.

FIG. 9 is a block diagram of a structure of a microprocessor that is formed using an SOI substrate.

FIG. 10 is a block diagram of a structure of an RFCPU that is formed using an SOI substrate.

FIG. 11 is a front view of an SOI substrate using mother glass as a base substrate.

FIG. 12A is a plan view of a pixel of a liquid crystal display device and FIG. 12B is a cross-sectional view along line J-K in FIG. 12A.

FIG. 13A is a plan view of a pixel of an electroluminescence display device and FIG. 13B is a cross-sectional view along line J-K in FIG. 13A.

FIG. 14A is an external view of a mobile phone, FIG. 14B is an external view of a digital player, and FIG. 14C is an external view of an electronic book.

FIG. 15 is a cross-sectional photograph of a TFT manufactured using an SOI substrate.

FIG. 16 is a graph showing characteristics of TFTs.

FIG. 17 is a graph in which rectification voltages are compared.

FIG. 18 is a photograph of an RTLS-RFID tag.

FIG. 19 is a block diagram of an RTLS-RFID tag.

FIG. 20 is a response signal waveform of an RTLS-RFID tag.

FIG. 21 is a graph of communication distance vs. output digital code of an RTLS-RFID tag.

FIG. 22 is an analysis result of crystal orientation of an SOI substrate.

FIG. 23 shows Raman spectra of SOI substrates and bulk silicon.

FIG. 24 is a cross-sectional photograph of a TFT manufactured using an SOI substrate.

FIGS. 25A and 25B are graphs of characteristics of TFTs.

FIG. 26 is graphs of characteristics of gate withstand voltages of capacitor TEGs each including a TFT.

FIG. 27 is a graph of a waveform of a nine-stage ring oscillator including a TFT.

FIG. 28 is a photograph of a CPU.

FIGS. 29A and 29B each are a shmoo plot of a CPU.

FIGS. 30A and 30B show an AFM photograph of an SOI substrate.

### BEST MODE FOR CARRYING OUT THE INVENTION

Embodiment modes and Embodiments according to the present invention will hereinafter be described referring to the accompanying drawings. It is easily understood by those who skilled in the art that the modes and details herein disclosed can be modified in various ways without departing from the spirit and scope of the present invention. Therefore, the present invention is not construed as being limited to the description of the following embodiment modes and embodiments. Note that the same elements are denoted by the same reference numerals throughout the drawings in the structures of the present invention described below.

### Embodiment Mode 1

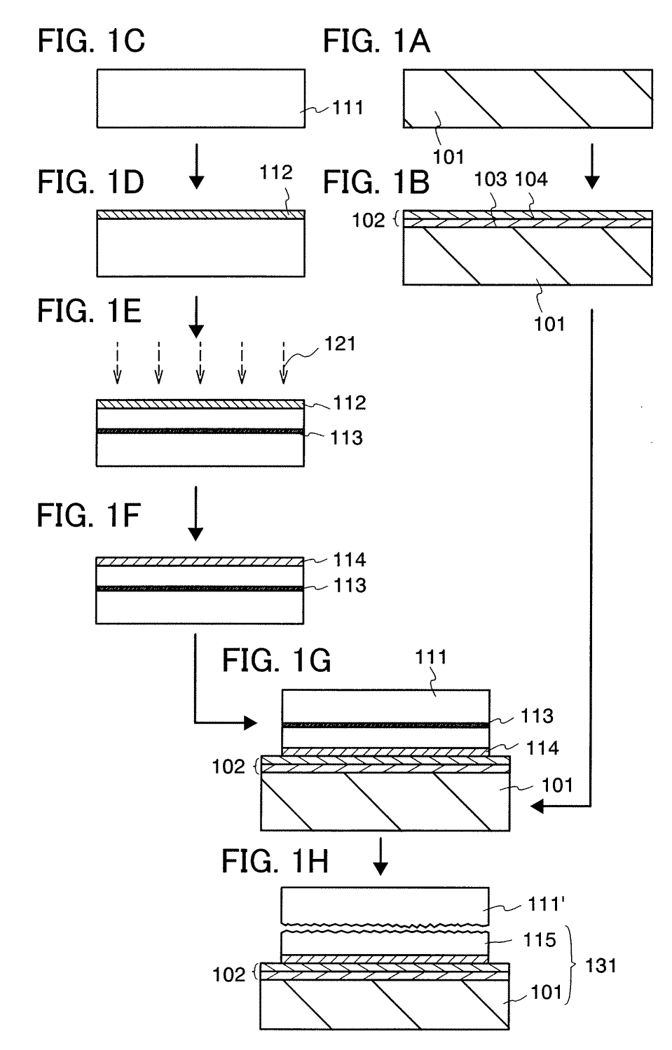

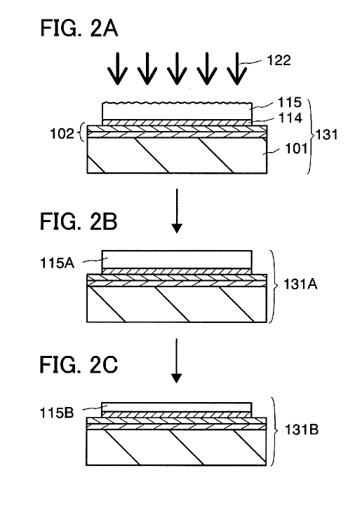

FIGS. 1A to 1H and FIGS. 2A to 2C are cross-sectional views showing an example of a method for manufacturing an SOI substrate used for a semiconductor device of the present invention. An example of a method for manufacturing an SOI substrate will be described below using FIGS. 1A to 1H and FIGS. 2A to 2C.

First, a base substrate 101 is prepared (see FIG. 1A). As the base substrate 101, a light-transmitting glass substrate which is used for an electronic product such as a liquid crystal display device can be used. It is preferable to use, as the glass substrate, a substrate having a coefficient of thermal expansion which is greater than or equal to 2.5×10⁻⁶/° C. and less than or equal to 5.0×10⁻⁶/° C. (preferably, greater than or equal to 3.0×10⁻⁶/° C. and less than or equal to 4.0×10⁻⁶/° C.) and a strain point which is equal to or higher than 580° C. and equal to or lower than 680° C. (preferably, equal to or higher than 600° C. and equal to or lower than 680° C.) in terms of heat resistance, cost, and the like. Further, it is preferable that the glass substrate be a non-alkali glass substrate. As a material of the non-alkali glass substrate, a glass material such as aluminosilicate glass, aluminoborosilicate glass, or barium borosilicate glass is used, for example.

The glass substrate may be produced by a fusion method or a float method. As for the glass substrate produced by a float method, the surface thereof may be polished, and a chemical solution treatment for removing an abrasive may be performed after the polishing.

Note that, as the base substrate 101, as well as the glass substrate, an insulating substrate which is formed of an insulating material, such as a ceramic substrate, a quartz substrate, or a sapphire substrate; a conductive substrate which is formed of a conductive material such as metal or stainless steel; a semiconductor substrate which is formed of a semiconductor such as silicon or gallium arsenide; or the like can be used.

Next, the base substrate 101 is cleaned, and an insulating layer 102 with a thickness which is greater than or equal to 10 nm and less than or equal to 400 nm is formed thereover (see FIG. 1B). The insulating layer 102 can employ a single-layer structure or a multilayer structure of two or more layers.

As a film included in the insulating layer 102, an insulating film containing silicon or germanium as its component such as a silicon oxide film, a silicon nitride film, a silicon oxynitride film, a silicon nitride oxide film, a germanium oxide film, a germanium nitride film, a germanium oxynitride film, or a germanium nitride oxide film can be used. Further, an insulating film including a metal oxide such as aluminum oxide, tantalum oxide, or hafnium oxide; an insulating film including a metal nitride such as aluminum nitride; an insulating film including a metal oxynitride such as an aluminum oxynitride film; or an insulating film including a metal nitride oxide such as an aluminum nitride oxide film can be used as well.

Note that, in this specification, an oxynitride is a substance that contains more oxygen than nitrogen, and a nitride oxide is a substance that contains more nitrogen than oxygen. For example, silicon oxynitride contains more oxygen than nitrogen and includes, for example, oxygen, nitrogen, silicon, and hydrogen at concentrations ranging from 50 at. % to 70 at. % inclusive, from 0.5 at. % to 15 at. % inclusive, from 25 at. % to 35 at. % inclusive, and from 0.1 at. % to 10 at. % inclusive, respectively. Further, silicon nitride oxide contains more nitrogen than oxygen and includes, for example, oxygen, nitrogen, silicon, and hydrogen at concentrations ranging from 5 at. % to 30 at. % inclusive, from 20 at. % to 55 at. % inclusive, from 25 at. % to 35 at. % inclusive, and from 10 at. % to 30 at. % inclusive, respectively. Note that the above-described ranges are ranges for the cases measured using Rutherford backscattering spectrometry (RBS) or hydrogen forward scattering (HFS). Moreover, the total for the content ratio of the constituent elements does not exceed 100 at. %.

In the case where a substrate including an impurity which reduces reliability of a semiconductor device such as an alkali metal or an alkaline earth metal is used as the base substrate 101, it is preferable that at least one layer of a film which can prevent such an impurity from diffusing from the base substrate 101 into a semiconductor layer be provided. As examples of such a film, a silicon nitride film, a silicon nitride oxide film, an aluminum nitride film, an aluminum nitride oxide film, or the like can be given. When such a film is included, the insulating layer 102 can serve as a barrier layer.

For example, in the case of forming the insulating layer 102 as a barrier layer with a single-layer structure, a silicon nitride film, a silicon nitride oxide film, an aluminum nitride film, or an aluminum nitride oxide film having a thickness greater than or equal to 10 nm and less than or equal to 200 nm can be formed.

In the case where the insulating layer 102 serves as a barrier layer and has a two-layer structure, any of the following structures can be employed: a stacked-layer film of a silicon nitride film and a silicon oxide film; a stacked-layer film of a silicon nitride film and a silicon oxynitride film; a stacked-layer film of a silicon nitride oxide film and a silicon oxide film; a stacked-layer film of a silicon nitride oxide film and a silicon oxynitride film; and the like. Note that it is preferable that, in each of the above-described two-layer structures, the film described first be a film formed on the top surface of the base substrate 101. Further, it is preferable that, as an upper layer, a film made of a material capable of relaxing stress be selected so that internal stress of a lower layer having a high blocking effect does not affect a semiconductor layer. Further, the thickness of the upper layer can be greater than or equal to 10 nm and less than or equal to 200 nm, and the thickness of the lower layer can be greater than or equal to 10 nm and less than or equal to 200 nm.

In this embodiment mode, the insulating layer 102 employs a two-layer structure in which the lower layer is a silicon nitride oxide film 103 formed by a plasma CVD method using SiH₄ and NH₃ as a process gas and the upper layer is a silicon oxynitride film 104 formed by a plasma CVD method using SiH₄ and N₂O as a process gas.

A semiconductor substrate is processed along with the process shown in FIGS. 1A and 1B. First, a semiconductor substrate 111 is prepared (see FIG. 1C). The semiconductor substrate 111 is thinned to be a semiconductor layer and is attached to the base substrate 101 so that an SOI substrate is manufactured. Note that, although a single-crystal semiconductor substrate is preferably used as the semiconductor substrate 111, a polycrystalline semiconductor substrate can be used as well. Alternatively, a substrate made of an element belonging to Group 4 of the periodic table, such as silicon, germanium, silicon-germanium, or silicon carbide. It is needless to say that a semiconductor substrate made of a compound semiconductor such as gallium arsenide or indium phosphide may be used as well.

Next, the semiconductor substrate 111 is cleaned. Then, after that, a protective film 112 is formed on the surface of the semiconductor substrate 111 (see FIG. 1D). The protective film 112 has an effect of preventing the semiconductor substrate 111 from being contaminated by an impurity at the time of ion irradiation, an effect of preventing the semiconductor substrate 111 from being damaged by bombardment of irradiation ions, and the like. The protection film 112 can be formed by depositing silicon oxide, silicon nitride, silicon nitride oxide, silicon oxynitride, or the like by a CVD method or the like. Further, the protective film 112 can also be formed by oxidizing or nitriding the semiconductor substrate 111.

Next, ion beams 121 including ions accelerated by electric field are applied to the semiconductor substrate 111 through the protective film 112, so that an embrittlement layer 113 is formed in a region at a predetermined depth from the surface of the semiconductor substrate 111 (see FIG. 1E). The depth of the region where the embrittlement layer 113 is formed can be controlled by the accelerating energy of the ion beams 121 and the incidence angle thereof. The embrittlement layer 113 is formed in a region at a depth the same or substantially the same as the average depth of introduced ions.

Depending on the depth at which the embrittlement layer 113 is formed, the thickness of the semiconductor layer which is separated from the semiconductor substrate 111 is determined. The depth at which the embrittlement layer 113 is formed is greater than or equal to 50 nm and less than or equal to 500 nm, and the preferable thickness of the semiconductor layer which is separated from the semiconductor substrate 111 is greater than or equal to 50 nm and less than or equal to 200 nm.

In order to irradiate the semiconductor substrate 111 with ions, an ion implantation apparatus or an ion doping apparatus can be used. In an ion implantation apparatus, a source gas is excited to produce ion species, the produced ion species are mass-separated, and ion species each having a predetermined mass is implanted in a process object. In an ion doping apparatus, a process gas is excited to produce ion species, the produced ion species are not mass-separated and are introduced into a process object. Note that, in an ion doping apparatus provided with a mass separator, ion irradiation with mass separation can be performed like in the ion implantation apparatus.

For example, an ion irradiation step with an ion doping apparatus can be performed in the following conditions:

Acceleration voltage is greater than or equal to 10 kV and less than or equal to 100 kV (preferably greater than or equal to 20 kV and less than or equal to 80 kV)

Dose is greater than or equal to 1×10¹⁶ ions/cm² and less than or equal to 4×10¹⁶ ions/cm²

Beam current density is 2 μA/cm² or more (preferably, 5 μA/cm² or more, and more preferably, 10 μA/cm² or more)

A hydrogen gas can be used for a source gas in the ion irradiation step. By using the hydrogen gas (H₂ gas), H⁺, H₂⁺, and H₃⁺ ions can be produced as ion species. In the case where the hydrogen gas is used as a source gas, it is preferable to perform irradiation with a larger amount of H₃⁺ ions. By irradiation with a larger amount of H₃⁺ ions, ion irradiation efficiency is improved compared to the case of irradiation with H⁺ ions and/or H₂⁺ ions. That is, irradiation time can be shortened. Further, separation from the embrittlement layer 113 becomes easier. Further, since the average penetration depth of ions can be made small by using H₃⁺ ions, the embrittlement layer 113 can be formed in a region at smaller depth from the surface of the semiconductor substrate 111.

When the ion implantation apparatus is used, it is preferable to implant H₃⁺ ions through mass separation. It is needless to say that H₂⁺ ions may be implanted.

When the ion doping apparatus is used, it is preferable that H₃⁺ ions be included at least 70% of the total amount of H⁺, H₂⁺, and H₃⁺ ions in the ion beams 121. It is more preferable that the proportion of H₃⁺ ions be greater than or equal to 80%. With a high proportion of H₃⁺ ions in this manner, the embrittlement layer 113 can contain hydrogen at a concentration of 1×10²⁰ atoms/cm³ or more. Note that separation of a semiconductor layer can be easy when the embrittlement layer 113 contains hydrogen at least 5×10²⁰ atoms/cm³.

As the source gas in the ion irradiation step, instead of a hydrogen gas, one or more kinds of gas selected from a rare gas such as a helium gas or an argon gas, a halogen gas typified by a fluorine gas or a chlorine gas, and a halogen compound gas such as a fluorine compound gas (e.g., BF₃) can be used. When helium is used for the source gas, the ion beams 121 with high proportion of He⁺ ions can be formed without mass separation. By using such ion beams as the ion beams 121, the embrittlement layer 113 can be formed efficiently.

Further, an ion irradiation step may be performed plural times as well to form the embrittlement layer 113. In this case, either different source gases or the same source gas may be used for the ion irradiation steps. For example, ion irradiation may be performed using a rare gas as a source gas, and then, ion irradiation may be performed using a hydrogen gas as a source gas. Alternatively, an ion irradiation may be performed first using a halogen gas or a halogen compound gas, and then, ion irradiation may be performed using a hydrogen gas.

After the embrittlement layer 113 is formed, the protective film 112 is removed by etching. Then, a bonding layer 114 is formed on the top surface of the semiconductor substrate 111 (see FIG. 1F). The bonding layer 114 can also be formed on the protective film 112 without removing the bonding layer 114.

The bonding layer 114 is a layer having a smooth, hydrophilic surface. As the bonding layer 114, an insulating film formed by chemical reaction, in particular, a silicon oxide film, is preferably used. The thickness of the bonding layer 114 can be greater than or equal to 10 nm and less than or equal to 200 nm. The preferable thickness is greater than or equal to 10 nm and less than or equal to 100 nm, and the more preferable thickness is greater than or equal to 20 nm and less than or equal to 50 nm. Note that it is necessary that the heat temperature of the semiconductor substrate 111 be a temperature at which an element or a molecule introduced in the embrittlement layer 113 is not released in the step for forming the bonding layer 114. Specifically, the heat temperature is preferably equal to or lower than 350° C.

When a silicon oxide film of the bonding layer 114 is formed by a plasma CVD method, an organosilane gas is preferably used as a silicon source gas. An oxygen (O₂) gas can be used as an oxygen source gas. As the organosilane gas, any of the following can be used: ethyl silicate (TEOS) (chemical formula: Si(OC₂H₅)₄); tetramethylsilane (TMS) (chemical formula: Si(CH₃)₄); tetramethylcyclotetrasiloxane (TMCTS); octamethylcyclotetrasiloxane (OMCTS); hexamethyldisilazane (HMDS); triethoxysilane (chemical formula: SiH(OC₂H₅)₃); trisdimethylaminosilane (chemical formula: SiH(N(CH₃)₂)₃); and the like. Further, as the silicon source gas, instead of the organosilane gas, silane (SiH₄), disilane (Si₂H₆), or the like can be used.

The silicon oxide film can also be formed by a thermal CVD method instead of a plasma CVD method. In this case, silane (SiH₄), disilane (Si₂H₆), or the like can be used as the silicon source gas, and an oxygen (O₂) gas, a dinitrogen monoxide (N₂O) gas, or the like can be used as the oxygen source gas. It is preferable that the heat temperature be greater than or equal to 200° C. and less than or equal to 500° C. Note that the bonding layer 114 is formed of an insulating material in many cases and, in this sense, can be included in the category of an insulating layer.

Next, the base substrate 101 and the semiconductor substrate 111 are attached to each other (see FIG. 1G). This attachment step is performed as follows: first, the base substrate 101 provided with the insulating layer 102 and the semiconductor substrate 111 provided with the bonding layer 114 are cleaned by ultrasonic cleaning or the like; and next, the insulating layer 102 and the bonding layer 114 are made in close contact with each other, so that the insulating layer 102 and the bonding layer 114 are bonded to each other. Note that, as bonding mechanism, mechanism relating to van der Waals' force, mechanism relating to hydrogen bonding, or the like is conceivable.

As described above, when a silicon oxide film formed by a plasma CVD method using organosilane, a silicon oxide film formed by a thermal CVD method, or the like is used as the bonding layer 114, the insulating layer 102 and the bonding layer 114 can be bonded at room temperature. Therefore, a low-heat-resistant substrate such as a glass substrate can be used as the base substrate 101.

Note that the formation of the insulating layer 102 can be omitted; however, this case is not described in this embodiment mode. In this case, the bonding layer 114 is bonded to the base substrate 101. In the case where the base substrate 101 is a glass substrate, the glass substrate and the bonding layer 114 can be bonded at room temperature by forming the bonding layer 114 of a silicon oxide film formed by a CVD method using organosilane, a silicon oxide film formed by a thermal CVD method, a silicon oxide film formed using siloxane as a source material, or the like.

In order to further increase the bonding force, there is a method in which, for example, a plasma treatment using a gas or a mixed gas selected from N₂, O₂, Ar, and NH₃, an oxygen plasma treatment, an ozone treatment, or the like is performed on the surface of the insulating layer 102 to make the surface hydrophilic. By this treatment, a hydroxyl is added to the surface of the insulating layer 102, so that a hydrogen bond can be formed at a bonding interface between the insulating layer 102 and the bonding layer 114. Note that, in the case where the insulating layer 102 is not formed, treatment for making the surface of the base substrate 101 hydrophilic may be performed.

It is preferable that, after the base substrate 101 and the semiconductor substrate 111 are made in close contact with each other, heat treatment or pressure treatment be performed. This is because the bonding force between the insulating layer 102 and the bonding layer 114 can be improved by performing heat treatment or pressure treatment. It is preferable that the temperature of the heat treatment be equal to or lower than an allowable temperature limit of the base substrate 101, and the heat temperature can be equal to or higher than 400° C. and equal to or lower than 700° C. For example, when a glass substrate is used as the base substrate 101, the strain point may be considered as the allowable temperature limit. The pressure treatment is performed so that force is applied in a direction perpendicular to the bonding interface, and the pressure to be applied is determined in consideration of strength of the base substrate 101 and the semiconductor substrate 111.

Next, the semiconductor substrate 111 is separated to a semiconductor substrate 111′ and a semiconductor layer 115 (see FIG. 1H). The separation of the semiconductor substrate 111 is performed by heating the semiconductor substrate 111 after the base substrate 101 and the semiconductor substrate 111 are attached to each other. The heat temperature of the semiconductor substrate 111 is, for example, equal to or higher than 400° C. and equal to or lower than 700° C., which depends on the allowable temperature limit of the base substrate.

By performing the heat treatment at a temperature in the range of 400° C. to 700° C. inclusive as described above, volume change of a minute vacancy formed in the embrittlement layer 113 occurs to generate a crack in the embrittlement layer 113. As a result of this, the semiconductor substrate 111 is separated along the embrittlement layer 113. Since the bonding layer 114 is bonded to the base substrate 101, the semiconductor layer 115 separated from the semiconductor substrate 111 remains over the base substrate 101. Further, since the bonding interface between the base substrate 101 and the bonding layer 114 is heated by this heat treatment, a covalent bond is formed at the bonding interface so that the bonding force at the bonding interface is improved.

Through the above-described steps, an SOI substrate 131 in which the semiconductor layer 115 is provided for the base substrate 101 is manufactured. The SOI substrate 131 is a substrate with a multilayer structure, in which the insulating layer 102, the bonding layer 114, and the semiconductor layer 115 are stacked in this order over the base substrate 101, and a bond is formed at the interface between the insulating layer 102 and the bonding layer 114. Note that a bond is formed at an interface between the base substrate 101 and the bonding layer 114 in the case where the insulating layer 102 is not provided.

Further, heat treatment at a temperature which is equal to or higher than 400° C. and equal to or lower than 700° C. inclusive can also be performed after the semiconductor substrate 111 is separated to form the SOI substrate 131. By this heat treatment, bonding force between the bonding layer 114 and the insulating layer 102 in the SOI substrate 131 can be further improved. It is needless to say that the upper limit of the heat temperature is set so as not to exceed the allowable temperature limit of the base substrate 101.

Defects due to the separation step or the ion irradiation step exist in the surface of the semiconductor layer 115, and planarity of the surface is lost. It is difficult to form a thin gate insulating layer having high withstand voltage on such a surface having roughness of the semiconductor layer 115. Therefore, planarization treatment is performed on the semiconductor layer 115. Further, a treatment for reducing the defects in the semiconductor layer 115 is performed because defects in the semiconductor layer 115 have an adverse effect on the performance and reliability of a transistor, such as increase of the localized state density at the interface between the semiconductor layer 115 and a gate insulating layer.

Planarization and reduction of defects of the semiconductor layer 115 are realized by irradiation of the semiconductor layer 115 with a laser beam 122 (see FIG. 2A). By irradiation with the laser beam 122 from the top surface side of the semiconductor layer 115, the top surface of the semiconductor layer 115 is melted. The semiconductor layer 115 is cooled and becomes solidified after the melting, thereby a semiconductor layer 115A in which the planarity of the top surface is improved can be obtained (see FIG. 2B). Since the laser beam 122 is used in the planarization treatment, the base substrate does not need to be heated so that temperature rise of the base substrate 101 can be suppressed. Therefore, a low-heat-resistant substrate such as a glass substrate can be used as the base substrate 101.

Note that it is preferable that the semiconductor layer 115 be partially melted by the irradiation with the laser beam 122. This is because, if the semiconductor layer 115 is completely melted, the semiconductor layer 115 is recrystallized due to disordered nucleation in the semiconductor layer 115 in a liquid phase so that crystallinity of the semiconductor layer 115A is lowered. By partial melting, crystal growth proceeds from a solid-phase part of the semiconductor layer 115, which is not melted. Accordingly, the defects of the semiconductor layer 115 are reduced and crystallinity is recovered. Note that complete melting refers that the semiconductor layer 115 is melted to the interface between the semiconductor layer 115 and the bonding layer 114 to be made in a liquid state. On the other hand, partial melting refers that the upper layer is melted to be made in a liquid phase whereas the lower layer is kept in a solid phase without being melted.

For the laser beam irradiation, a continuous-wave laser (CW laser) or a pulsed laser (preferably with a repetition rate about in the range of 10 to 100 Hz) can be used. Specifically, as the continuous-wave laser, the following can be used: an Ar laser, a Kr laser, a CO₂ laser, a YAG laser, a YVO₄ laser, a YLF laser, a YAlO₃ laser, a GdVO₄ laser, a Y₂O₃ laser, a ruby laser, an alexandrite laser, a Ti:sapphire laser, a helium-cadmium laser, or the like. As the pulsed laser, the following can be used: an Ar laser, a Kr laser, an excimer (ArF, KrF, XeCl, or the like) laser, a CO₂ laser, a YAG laser, a YVO₄ laser, a YLF laser, a YAlO₃ laser, a GdVO₄ laser, a Y₂O₃ laser, a ruby laser, an Alexandrite laser, a Ti:sapphire laser, a copper vapor laser, a gold vapor laser, or the like. Note that such a pulsed laser can be treated in the same manner as a continuous-wave laser when the repetition rate is increased. It is preferable that a pulsed laser beam be used for partial melting; however, the present invention is not limited thereto.

It is necessary that the wavelength of the laser beam 122 be set to a wavelength which can be absorbed by the semiconductor layer 115. The wavelength may be determined in consideration of the skin depth of the laser beam and the like. For example, the wavelength can be set in the range of 250 to 700 nm inclusive. Further, the irradiation energy density of the laser beam 122 can be determined in consideration of the wavelength of the laser beam 122, the skin depth of the laser beam, the thickness of the semiconductor layer 115, or the like. For example, the irradiation energy density of the laser beam 122 may be set in the range of 300 to 800 mJ/cm² inclusive.

Note that, when the thickness of the semiconductor layer 115 is increased to greater than 50 nm by controlling the depth of ions that are introduced in the ion irradiation step, control of the irradiation energy density of the laser beam 122 becomes easy. Accordingly, improvement of surface planarity and crystallity of the semiconductor layer 115 by irradiation with the laser beam 122 can be realized effectively. Note that, since the irradiation energy density of the laser beam 122 needs to be higher as the thickness of the semiconductor layer 115 is increased, the thickness of the semiconductor layer 115 is preferably less than or equal to 200 nm.

The irradiation with the laser beam 122 can be performed in an atmosphere containing oxygen such as an air atmosphere or an inert atmosphere such as a nitrogen atmosphere. In order to perform irradiation with the laser beam 122 in an inert atmosphere, the irradiation with the laser beam 122 may be performed in an airtight chamber while the atmosphere in the chamber may be controlled. In the case where the chamber is not used, an nitrogen atmosphere can be formed by blowing an inert gas such as a nitrogen gas to the surface which is irradiated with the laser beam 122.

Note that the inert atmosphere such as nitrogen has higher effect of improving planarity of the semiconductor layer 115 than the air atmosphere. In addition, the inert atmosphere has higher effect of suppressing generation of cracks and ridges than the air atmosphere, and the applicable energy range for the laser beam 122 is widened. Note that, in the above-described inert atmosphere, the concentration of oxygen is less than or equal to 0.1%, preferably less than or equal to 0.01%, and more preferably less than or equal to 0.001%.

After an SOI substrate 131A including the semiconductor layer 115A shown in FIG. 2B is formed by the irradiation with the laser beam 122, a thinning step for reducing the thickness of the semiconductor layer 115A is performed (see FIG. 2C).

In order to thin the semiconductor layer 115A, one of dry etching or wet etching or a combination of both the etchings may be performed. For example, in the case where the semiconductor substrate 111 is a silicon substrate, the semiconductor layer 115A can be thinned by dry etching using SF₆ and O₂ as a process gas. Further, Cl₂ may be used as a process gas.

By the etching treatment, an SOI substrate 131B including a thin semiconductor layer 115B can be manufactured (see FIG. 2C). Since the surface of the semiconductor layer 115A is planarized in advance by the irradiation with the laser beam 122, this thinning step can be performed not by etch-back treatment but by etching treatment. It is needless to say that etch-back treatment may be employed. In this thinning step, the thickness of the semiconductor layer 115B is reduced to preferably less than or equal to 100 nm and greater than or equal to 5 nm, and more preferably less than or equal to 50 nm and greater than or equal to 5 nm.

Note that, although the etching treatment or etch-back treatment is performed after the surface is planarized by laser beam irradiation in this embodiment mode, the present invention is not limited thereto. For example, etching treatment or etch-back treatment may be performed before laser beam irradiation. In this case, roughness or defects in the surface of the semiconductor layer can be reduced by the etching treatment or etch-back treatment. Alternatively, etching treatment or etch-back treatment may be performed before and after the laser beam irradiation. Further alternatively, the laser beam irradiation and either etching treatment or etch-back treatment may be alternately repeated. By using laser beam irradiation and etching treatment (or etch-back treatment) in combination as described above, roughness, defects, and the like of the surface of the semiconductor layer can be significantly reduced as compared to the case of using only one of laser beam irradiation or etching treatment (or etch-back treatment).

Through the above-described steps, an SOI substrate can be manufactured. Note that, in order to increase the area of an SOI substrate, a plurality of the semiconductor layers 115B may be attached to the one base substrate 101. For example, the process described using FIGS. 1C to 1F is repeated plural times, and a plurality of the semiconductor substrates 111 each provided with the embrittlement layer 113 are prepared. Next, the bonding step of FIG. 1G is repeated plural times, so that the plurality of semiconductor substrates 111 are fixed to the one base substrate 101. Then, the heating step of FIG. 1H is performed to separate the semiconductor substrates 111, so that the SOI substrate 131 in which the plurality of semiconductor layers 115 are fixed to the base substrate 101 is manufactured. Then, through the steps of FIGS. 2A to 2C, the SOI substrate 131B in which the plurality of semiconductor layers 115B are bonded to the base substrate 101 can be manufactured.

As described in this embodiment mode, by combining the planarization step of the semiconductor layer by laser beam irradiation and etching treatment (or a etch-back treatment), the semiconductor layer 115B with a thickness less than or equal to 100 nm, with high planarity, and with less defects can be formed. That is, even when a glass substrate is used as the base substrate 101 and an ion doping apparatus is used for the formation of the embrittlement layer 113, the SOI substrate 131B in which the semiconductor layer 115B having the above-described characteristics is bonded can be manufactured.

By manufacturing a transistor using the SOI substrate 131B, thinning of a gate insulating layer and reduction of the localized interface state density between the SOI substrate and the gate insulating layer can be realized. In addition, by making the semiconductor layer 115B thin, a fully-depleted transistor can be manufactured using a single-crystal semiconductor layer over a glass substrate. Accordingly, a transistor with high performance and high reliability which can, for example, operate at high speed and have a low subthreshold value, high electron field-effect mobility, and low voltage consumption can be manufactured over a base substrate.

Further, since CMP treatment which is not suited to increase in area is not needed, increase in area of a high-performance semiconductor device can be realized. It is needless to say that, according to this embodiment mode, a favorable semiconductor device can be provided not only in the case of using a large-area substrate but also in the case of using a small substrate, which is desirable. Note that surface characteristics of a semiconductor layer obtained through the process in this embodiment mode will be described below, where Ra means arithmetical mean roughness, RMS means root-mean-square roughness, and P-V means the maximum difference in height. Note that the value of P-V is greatly affected by a minute defect in some cases; therefore, it is more preferable that Ra or RMS be used as an evaluation parameter.

Ra: less than or equal to 7 nm

RMS: less than or equal to 10 nm

P-V: less than or equal to 250 nm

Note that the above-described parameters in the case of using CMP are as follows:

Ra: less than 1 nm

RMS: less than 1 nm

P-V: less than 5 nm

From the above, it can be found that the parameters of the surface of the semiconductor layer formed without using CMP, of the present invention, are within the following ranges:

Ra: greater than or equal to 1 nm and less than or equal to 7 nm (preferably, greater than or equal to 1 nm and less than or equal to 3 nm)

RMS: greater than or equal to 1 nm and less than or equal to 10 nm (preferably, greater than or equal to 1 mm and less than or equal to 4 nm)

P-V: greater than or equal to 5 nm and less than or equal to 250 nm (preferably, greater than or equal to 5 nm and less than or equal to 50 nm)

Note that the main surface of the semiconductor substrate used in this embodiment mode may be a (100) plane, a (110) plane, or a (111) plane. The case of using a (100) plane, which can reduce the interface state density, is suited to manufacturing of an electric-field effect transistor. The case of using a (110) plane, which forms a close bond between an element included in a bonding layer and an element included in a semiconductor (e.g., a silicon element), improves adhesion between an insulating layer and a semiconductor layer. That is, separation of the semiconductor layer can be suppressed. In addition, atoms are densely arranged in a (110) plane, and thus, the planarity of a single-crystal-silicon layer in an SOI substrate is improved as compared to the case of using another plane. That is, a transistor manufactured using such a semiconductor layer has excellent characteristics. Note that a (110) plane also has an advantage in that the young's modulus is higher than that of a (100) plane and separation can be easily performed.

### Embodiment Mode 2

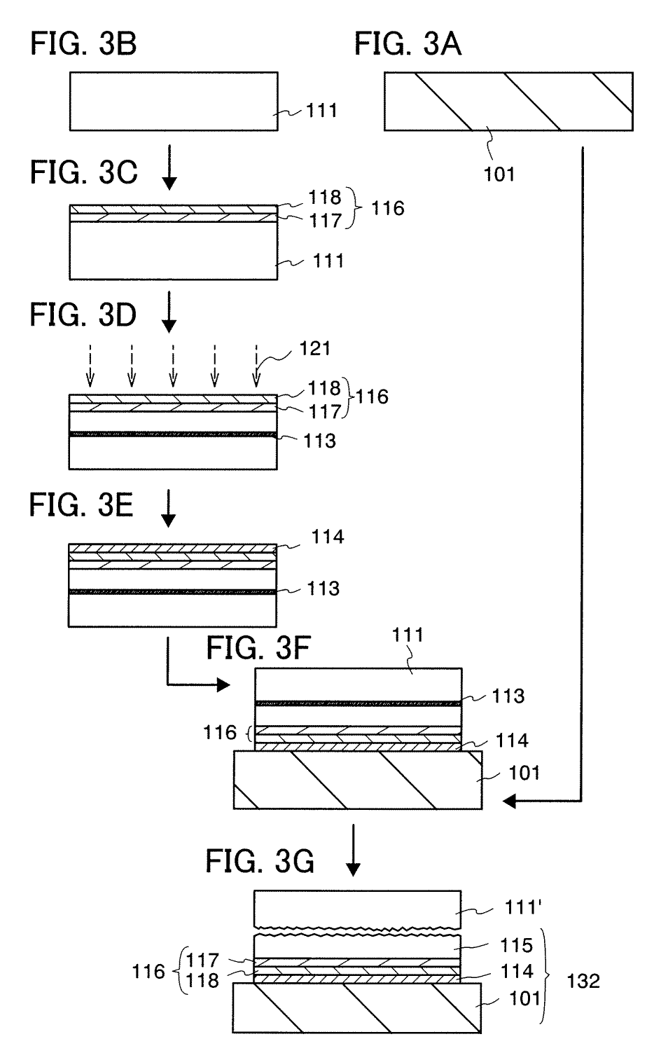

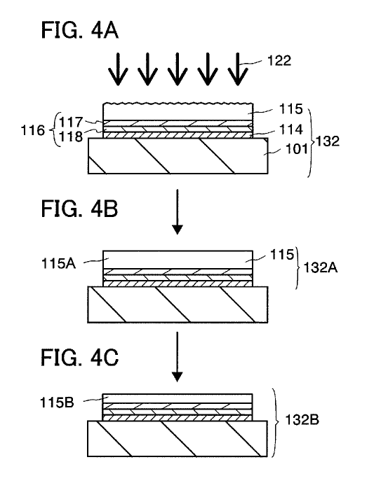

FIGS. 3A to 3G and FIGS. 4A to 4C are cross-sectional views showing another example of the method for manufacturing an SOI substrate used for the semiconductor device of the present invention. Another example of the method for manufacturing an SOI substrate will be described below using FIGS. 3A to 3G and FIGS. 4A to 4C.

As described in Embodiment mode 1 using FIG. 1A, the base substrate 101 which serves as a base substrate of an SOI substrate is prepared (see FIG. 3A). FIG. 3A is a cross-sectional view of the base substrate 101. Further, as described using FIG. 1C, the semiconductor substrate 111 is prepared (see FIG. 3B). FIG. 3B is a cross-sectional view of the semiconductor substrate 111.

Next, the semiconductor substrate 111 is cleaned. Then, an insulating layer 116 is formed on the surface of the semiconductor substrate 111 (see FIG. 3C). The insulating layer 116 can employ a single-layer structure or a multilayer structure of two or more layers. The thickness of the insulating layer 116 can be equal to or more than 10 nm and less than or equal to 400 nm.

As a film included in the insulating layer 116, an insulating film containing silicon or germanium as its component such as a silicon oxide film, a silicon nitride film, a silicon oxynitride film, a silicon nitride oxide film, a germanium oxide film, a germanium nitride film, a germanium oxynitride film, or a germanium nitride oxide film can be used. Further, an insulating film including a metal oxide such as aluminum oxide, tantalum oxide, or hafnium oxide; an insulating film including a metal nitride such as aluminum nitride; an insulating film including a metal oxynitride such as an aluminum oxynitride film; or an insulating film including a metal nitride oxide such as an aluminum nitride oxide film can be used as well.

As a method for forming an insulating film included in the insulating layer 116, a CVD method, a sputtering method, a method of oxidizing (or nitriding) the semiconductor substrate 111, or the like can be used.

In the case where a substrate including an impurity which reduces reliability of a semiconductor device such as an alkali metal or an alkaline earth metal is used as the base substrate 101, it is preferable that at least one layer of a film which can prevent such an impurity from diffusing from the base substrate 101 into a semiconductor layer of an SOI substrate be provided. As examples of such a film, a silicon nitride film, a silicon nitride oxide film, an aluminum nitride film, an aluminum nitride oxide film, and the like can be given. When such a film is included, the insulating layer 102 can serve as a barrier layer.

For example, in the case of forming the insulating layer 116 as a barrier layer with a single-layer structure, a silicon nitride film, a silicon nitride oxide film, an aluminum nitride film, or an aluminum nitride oxide film having a thickness greater than or equal to 10 nm and less than or equal to 200 nm can be formed.

In the case where the insulating layer 116 serves as a barrier layer and has a two-layer structure, any of the following structures can be employed: a stacked-layer film of a silicon oxide film and a silicon nitride film; a stacked-layer film of a silicon oxynitride film and a silicon nitride film; a stacked-layer film of a silicon oxide film and a silicon nitride oxide film; a stacked-layer film of a silicon oxynitride film and a silicon nitride oxide film; and the like. Note that it is preferable that, in each of the two-layer structures described above, the film described first be a film formed on the semiconductor substrate 111 side (a lower layer). Further, it is preferable that, as a lower layer, a film made of a material capable of relaxing stress be selected so that internal stress of an upper layer having a high blocking effect does not affect the semiconductor layer. Further, the thickness of the upper layer can be greater than or equal to 10 nm and less than or equal to 200 nm, and the thickness of the lower layer can be greater than or equal to 10 nm and less than or equal to 200 nm.

In this embodiment mode, the insulating layer 116 employs a two-layer structure in which the lower layer is a silicon oxynitride film 117 formed by a plasma CVD method using SiH₄ and N₂O as a process gas and the upper layer is a silicon nitride oxide film 118 formed by a plasma CVD method using SiH₄ and NH₃ as a process gas.

Next, the ion beams 121 including ions accelerated by electric field are applied to the semiconductor substrate 111 through the insulating layer 116, so that the embrittlement layer 113 is formed in a region at a predetermined depth from the surface of the semiconductor substrate 111 (see FIG. 3D). This step can be performed in a similar manner to the formation of the embrittlement layer 113 described using FIG. 1E. The insulating layer 116 has an effect of preventing the semiconductor substrate 111 from being contaminated by an impurity at the time of ion irradiation, an effect of preventing the semiconductor substrate 111 from being damaged by bombardment of irradiation ions, and the like.

After the embrittlement layer 113 is formed, the bonding layer 114 is formed on the insulating layer 116 (see FIG. 3E).

Note that, although the bonding layer 114 is formed after the ion irradiation step in this embodiment mode, the bonding layer 114 may be formed before the ion irradiation step as well. In this case, after the formation of the insulating layer 116 in FIG. 3C, the bonding layer 114 is formed on the insulating layer 116, and the semiconductor substrate 111 is irradiated with the ion beams 121 through the bonding layer 114 and the insulating layer 116 in the step of FIG. 3D.

Further, as described in Embodiment Mode 1, the ion irradiation can also be performed after formation of the protective film 112. In this case, after the steps of FIGS. 1C to 1E, the protective film 112 may be removed, and the insulating layer 116 and the bonding layer 114 may be formed over the semiconductor substrate 111.

Next, the base substrate 101 and the semiconductor substrate 111 are attached to each other (see FIG. 3F). This attachment step is performed as follows: first, respective surfaces of the base substrate 101 and the bonding layer 114, which form a bonding interface, are cleaned by a method such as ultrasonic cleaning; and next, the base substrate 101 and the bonding layer 114 are made in close contact with each other by a similar step to the bonding step described using FIG. 1G so that the base substrate 101 and the bonding layer 114 are bonded to each other.

Before bonding the base substrate 101 and the bonding layer 114, the surface of the base substrate 101 may be made hydrophilic by performing oxygen plasma treatment or ozone treatment thereto. As a result of this, bonding force between the base substrate 101 and the bonding layer 114 can be increased. Further, after the base substrate 101 and the bonding layer 114 are made in close contact with each other, heat treatment or pressure treatment described in Embodiment Mode 1 can also be performed in order to increase the bonding force.

Next, the semiconductor substrate 111 is separated to the semiconductor substrate 111′ and the semiconductor layer 115 (see FIG. 3G). The separation step described in this embodiment mode can be performed in a similar manner to the separation step described using FIG. 1H. The separation of the semiconductor substrate 111 is performed by heating the semiconductor substrate 111 after the base substrate 101 and the semiconductor substrate 111 are attached to each other. The heat temperature of the semiconductor substrate 111 is, for example, equal to or higher than 400° C. and equal to or lower than 700° C., which depends on the allowable temperature limit of the base substrate.

Through the above-described steps, an SOI substrate 132 in which the semiconductor layer 115 is provided over the base substrate 101 is manufactured. The SOI substrate 132 is a substrate with a multilayer structure, in which the bonding layer 114, the insulating layer 116, and the semiconductor layer 115 are stacked in this order over the base substrate 101, and a bond is formed at the interface between the base substrate 101 and the bonding layer 114.

After that, a planarization step of irradiating the SOI substrate 132 with the laser beam 122 is performed (see FIG. 4A). This planarization step can be performed in a similar manner to the case shown in FIG. 2A. As shown in FIG. 4A, the irradiation with the laser beam 122 is conducted on an upper surface side of the semiconductor layer 115 to partially melt the semiconductor layer 115, so that the semiconductor layer 115A in which the planarity is increased and the number of defects is reduced is formed (see FIG. 4B).

After an SOI substrate 132A including the semiconductor layer 115A is formed by the irradiation with the laser beam 122, a thinning step of the semiconductor layer in which the semiconductor layer 115A is thinned is performed (see FIG. 4C). This thinning step can be performed in a similar manner to the thinning step of FIG. 2C, and the semiconductor layer 115A is etched (or etch-backed) to reduce the thickness of the semiconductor layer 115A. In this thinning step, the thickness of the semiconductor layer 115B is controlled to be preferably less than or equal to 100 nm and greater than or equal to 5 nm, and more preferably less than or equal to 50 nm and greater than or equal to 5 nm.

Note that, although the etching treatment or etch-back treatment is performed after the surface is planarized by laser beam irradiation in this embodiment mode, the present invention is not limited thereto. For example, etching treatment or etch-back treatment may be performed before laser beam irradiation. In this case, roughness or defects in the surface of the semiconductor layer can be reduced by the etching treatment or etch-back treatment. Alternatively, etching treatment or etch-back treatment may be performed before and after laser beam irradiation. Further alternatively, laser beam irradiation and either etching treatment or etch-back treatment may be alternately repeated. By using laser beam irradiation and etching treatment (or etch-back treatment) in combination as described above, roughness, defects, and the like of the surface of the semiconductor layer can be significantly reduced as compared to the case of using only one of laser beam irradiation or etching treatment (or etch-back treatment).

Through the above-described steps shown in FIGS. 3A to 3G and FIGS. 4A to 4C, an SOI substrate 132B including the semiconductor layer 115B can be formed.

Note that, as is in Embodiment Mode 1, also according to this process described in this embodiment mode, the SOI substrate 132B in which a plurality of the semiconductor layers 115B are attached to the one base substrate 101 can be manufactured. For example, the process described with reference to FIGS. 3B to 3E is repeated plural times, so that a plurality of the semiconductor substrates 111 each provided with the embrittlement layer 113 are prepared. Next, the bonding step of FIG. 3F is repeated plural times, so that the plurality of semiconductor substrates 111 are fixed to the one base substrate 101. Then, the heating step of FIG. 3G is performed to separate the semiconductor substrates 111, so that the SOI substrate 132 in which the plurality of semiconductor layers 115 are fixed to the base substrate 101 is manufactured. Then, through the steps of FIGS. 4A to 4C, the SOI substrate 132B in which the plurality of semiconductor layers 115B are attached to the base substrate 101 can be formed.

As described in this embodiment mode, by combining the planarization step of the semiconductor layer by laser beam irradiation and etching treatment (or etch-back treatment), the semiconductor layer 115B with a thickness less than or equal to 100 nm, with high planarity, and with less defects can be formed. That is, even when a glass substrate is used as the base substrate 101 and an ion doping apparatus is used for the formation of the embrittlement layer 113, the SOI substrate 132B in which the semiconductor layer 115B having the above-described characteristics is bonded can be manufactured.

By manufacturing a transistor using the SOI substrate 132B, thinning of a gate insulating layer and reduction of the localized interface state density between the SOI substrate and the gate insulating layer can be realized. In addition, by making the semiconductor layer 115B thin, a fully-depleted transistor can be manufactured using a single-crystal semiconductor layer over a glass substrate. Accordingly, a transistor with high performance and high reliability which can, for example, operate at high speed and have a low subthreshold value, high electron field-effect mobility, and low voltage consumption can be manufactured over a base substrate.

Further, since CMP treatment which is not suited to increase in area is not needed, increase in area of a high-performance semiconductor device can be realized. It is needless to say that, according to this embodiment mode, a favorable semiconductor device can be provided not only in the case of using a large-area substrate but also in the case of using a small substrate, which is desirable. Note that surface characteristics of the semiconductor layer obtained through the process in this embodiment mode are similar to those in Embodiment Mode 1.

Note that the main surface of the semiconductor substrate used in this embodiment mode may be a (100) plane, a (110) plane, or a (111) plane. The case of using a (100) plane, which can reduce the interface state density, is suited to manufacturing of an electric-field effect transistor. The case of using a (110) plane, which forms a close bond between an element included in a bonding layer and an element included in a semiconductor (e.g., a silicon element), improves adhesion between an insulating layer and a semiconductor layer. That is, separation of the semiconductor layer can be suppressed. In addition, atoms are densely arranged in a (110) plane, and thus, the planarity of a single-crystal-silicon layer in an SOI substrate is improved as compared to the case of using another plane. That is, a transistor manufactured using such a semiconductor layer has excellent characteristics. Note that a (110) plane also has an advantage in that the young's modulus is higher than that of a (100) plane and separation can be easily performed.

This embodiment mode can be combined with Embodiment Mode 1 as appropriate.

### Embodiment Mode 2

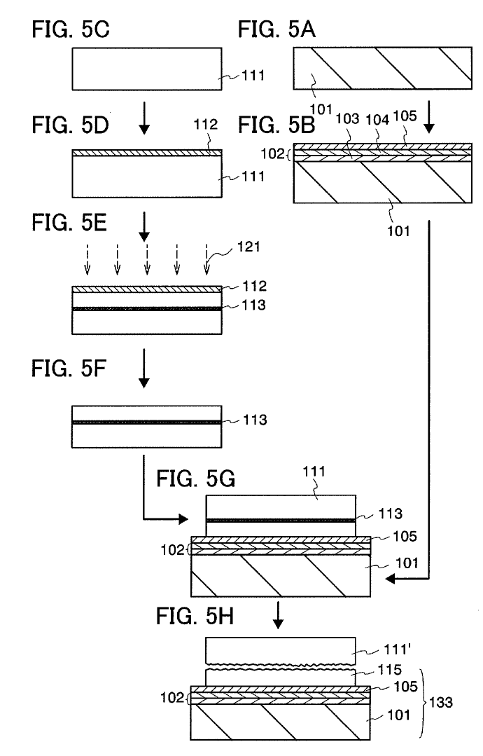

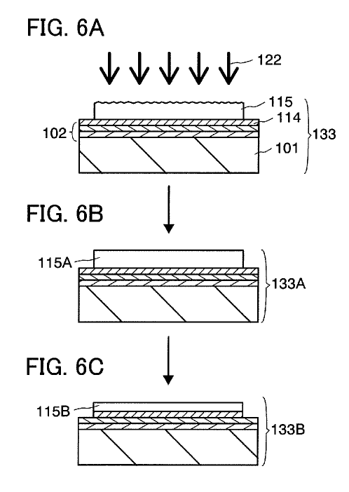

FIGS. 5A to 5H and FIGS. 6A to 6C are cross-sectional views showing another example of the method for manufacturing an SOI substrate used for the semiconductor device of the present invention. Another example of the method for manufacturing an SOI substrate will be described below using FIGS. 5A to 5H and FIGS. 6A to 6C.

As described in Embodiment mode 1 using FIG. 1A, the base substrate 101 which serves as a base substrate of an SOI substrate is prepared (see FIG. 5A), and the insulating layer 102 is formed over the base substrate 101. Also in this embodiment mode, the insulating layer 102 is a two-layer film of the silicon nitride oxide film 103 and the silicon oxynitride film 104. Next, a bonding layer 105 is formed over the insulating layer 102 (see FIG. 5B). This bonding layer 105 can be formed in a similar manner to the bonding layer 114 formed over the semiconductor substrate 111, described in Embodiment Mode 1 or 2.

FIGS. 5C to 5E show the same process as shown in FIGS. 1C to 1E. As described in Embodiment Mode 1, the protective film 112 is formed over the semiconductor substrate 111, and the embrittlement layer 113 is formed in the semiconductor substrate 111. After the formation of the embrittlement layer 113, as shown in FIG. 5F, the protective film 112 is removed. Note that, after removing the protective film 112, the bonding layer 114 can also be formed as is in FIG. 1F. Alternatively, the following bonding step may be performed while the protective film 112 remains. Further alternatively, the bonding layer 114 can be formed over the protective film 112 while the protective film 112 remains.

Next, the base substrate 101 and the semiconductor substrate 111 are attached to each other (see FIG. 5G). This bonding step can be performed in a similar manner to the bonding step described using FIG. 1G in which the semiconductor substrate 111 and the bonding layer 105 are made in close contact with each other so that the semiconductor substrate 111 and the bonding layer 105 are bonded to each other.

Before bonding the semiconductor substrate 111 and the bonding layer 105, the surface of the semiconductor substrate 111 may be made hydrophilic by performing oxygen plasma treatment or ozone treatment thereto. Further, after the semiconductor substrate 111 and the bonding layer 105 are bonded to each other, heat treatment or pressure treatment described in Embodiment Mode 1 can be performed in order to increase the bonding force.

Next, the semiconductor substrate 111 is separated to the semiconductor substrate 111′ and the semiconductor layer 115 (see FIG. 5H). The separation step described in this embodiment mode can be performed in a similar manner to the separation step described using FIG. 1H. That is, the semiconductor substrate 111 may be heated at a temperature equal to or higher than 400° C. and equal to or lower than 700° C. after the semiconductor substrate 111 and the bonding layer 105 are bonded to each other. It is needless to say that the upper limit of the heat temperature is set so as not to exceed a strain point of the base substrate 101.

Through the above-described steps, an SOI substrate 133 in which the semiconductor layer 115 is provided over the base substrate 101 is manufactured. The SOI substrate 133 is a substrate with a multilayer structure, in which the insulating layer 102, the bonding layer 105, and the semiconductor layer 115 are stacked in this order, and a bond is formed at the interface between the semiconductor layer 115 and the bonding layer 105.

After that, a planarization step of irradiating the SOI substrate 133 with the laser beam 122 is performed (see FIG. 6A). This planarization step can be performed in a similar manner to the case shown in FIG. 2A. As shown in FIG. 6A, the irradiation with the laser beam 122 is conducted on an upper surface side of the semiconductor layer 115 to partially melt the semiconductor layer 115, so that the semiconductor layer 115A in which the planarity is increased and the number of defects is reduced is formed (see FIG. 6B).

After an SOI substrate 133A including the semiconductor layer 115A is formed by the irradiation with the laser beam 122, a thinning step of the semiconductor layer in which the semiconductor layer 115A is thinned is performed (see FIG. 6C). This thinning step can be performed in a similar manner to the thinning step of FIG. 2C, and the semiconductor layer 115A is etched (or etch-backed) to reduce the thickness of the semiconductor layer 115A. In this thinning step, the thickness of the semiconductor layer 115B is controlled to be preferably less than or equal to 100 nm and greater than or equal to 5 nm, and more preferably less than or equal to 50 nm and greater than or equal to 5 nm.

Through the above-described steps shown in FIGS. 5A to 5H and FIGS. 6A to 6C, an SOI substrate 133B including the semiconductor layer 115B can be formed.

Note that, as is in Embodiment Mode 1, also according to this process described in this embodiment mode, the SOI substrate 133B in which a plurality of the semiconductor layers 115B are attached to the one base substrate 101 can be manufactured. For example, the process described using FIGS. 5C to 5F is repeated plural times, so that a plurality of the semiconductor substrates 111 each provided with the embrittlement layer 113 are prepared. Next, the bonding step of FIG. 5G is repeated plural times, so that the plurality of semiconductor substrates 111 are fixed to the one base substrate 101. Then, the heating step of FIG. 5H is performed to separate the semiconductor substrates 111, so that the SOI substrate 133 in which the plurality of semiconductor layers 115 are fixed to the base substrate 101 is manufactured. Then, through the steps of FIGS. 6A to 6C, the SOI substrate 133B in which the plurality of semiconductor layers 115B are attached to the base substrate 101 can be formed.

As described in this embodiment mode, by combining the planarization step of the semiconductor layer by laser beam irradiation and etching treatment (or etch-back treatment), the semiconductor layer 115B with a thickness less than or equal to 100 nm, with high planarity, and with less defects can be formed. That is, even when a glass substrate is used as the base substrate 101 and an ion doping apparatus is used for the formation of the embrittlement layer 113, the SOI substrate 133B in which the semiconductor layer 115B having the above-described characteristics is bonded can be manufactured.

By manufacturing a transistor using the SOI substrate 133B, thinning of a gate insulating layer and reduction of the localized interface state density between the SOI substrate and the gate insulating layer can be realized. In addition, by making the semiconductor layer 115B thin, a fully-depleted transistor can be manufactured using a single-crystal semiconductor layer over a glass substrate. Accordingly, a transistor with high performance and high reliability which can, for example, operate at high speed and have a low subthreshold value, high electron field-effect mobility, and low voltage consumption can be manufactured over a base substrate.

Further, since CMP treatment which is not suited to increase in area is not needed, increase in area of a high-performance semiconductor device can be realized. It is needless to say that, according to this embodiment mode, a favorable semiconductor device can be provided not only in the case of using a large-area substrate but also in the case of using a small substrate, which is desirable. Note that surface characteristics of the semiconductor layer obtained through the process in this embodiment mode are similar to those in Embodiment Mode 1.

Note that the main surface of the semiconductor substrate used in this embodiment mode may be a (100) plane, a (110) plane, or a (111) plane. The case of using a (100) plane, which can reduce the interface state density, is suited to manufacturing of an electric-field effect transistor. The case of using a (110) plane, which densely form a bond between an element included in a bonding layer and an element included in a semiconductor (e.g., a silicon element), improves adhesion between an insulating layer and a semiconductor layer. That is, separation of the semiconductor layer can be suppressed. In addition, atoms are densely arranged in a (110) plane, and thus, the planarity of a single-crystal-silicon layer in an SOI substrate is improved as compared to the case of using another plane. That is, a transistor manufactured using such a semiconductor layer has excellent characteristics. Note that a (110) plane also has an advantage in that the young's modulus is higher than that of a (100) plane and separation can be easily performed.

This embodiment mode can be combined with Embodiment Mode 1 or 2 as appropriate.

### Embodiment Mode 4

In each of Embodiment Modes 1 to 3, before the irradiation of the semiconductor layer 115 with the laser beam 122, a thinning step in which the semiconductor layer 115 is thinned by etching treatment (or etch-back treatment) can be performed. In the case of using an ion doping apparatus for the formation of the embrittlement layer 113, it is difficult to control the thickness of the semiconductor layer 115 to less than or equal to 100 nm. Therefore, the semiconductor layer 115 just after the separation is relatively thick. When the semiconductor layer 115 is thick, the irradiation energy density of the laser beam 122 needs to be high, and accordingly, the applicable range of the irradiation energy density becomes narrower, and it becomes difficult to planarize the semiconductor layer 115 and recover crystallinity of the semiconductor layer 115 with high yield by irradiation with the laser beam 122.

Therefore, when the thickness of the semiconductor layer 115 exceeds 200 nm, it is preferable that the thickness of the semiconductor layer 115 be decreased to less than or equal to 200 nm and then irradiated with the laser beam 122. With the above-described thinning treatment, the thickness of the semiconductor layer 115 is preferably decreased to greater than or equal to 60 nm and less than or equal to 150 nm.

Specifically, thinning of the semiconductor layer can be realized as follows: first, the semiconductor layer 115 is thinned by etching treatment or etch-back treatment and then irradiated with the laser beam 122; and then, etching treatment or etch-back treatment is performed again on the semiconductor layer, so that the thickness of the semiconductor layer is further reduced to a desired thickness. Note that, if the semiconductor layer 115 can be thinned to a desired thickness by thinning before the irradiation with the laser beam 122, the thinning step after the irradiation with the laser beam 122 can be omitted.

This embodiment mode can be combined with any of Embodiment Modes 1 to 3 as appropriate.

### Embodiment Mode 5

By each of the methods for manufacturing an SOI substrate described using FIGS. 1A to 1H, FIGS. 2A to 2C, FIGS. 3A to 3G, FIGS. 4A to 4C, FIGS. 5A to 5H, and FIGS. 6A to 6C, various kinds of glass substrates such as a non-alkaline glass substrate can be applied for the base substrate 101. Therefore, by using a glass substrate as the base substrate 101, a large-area SOI substrate with each side over one meter can be manufactured. When a plurality of semiconductor elements are formed over such a large-area substrate which is supplied for manufacturing a semiconductor, a liquid crystal display device, an electroluminescent display device, and the like can be manufactured. In addition to such display devices, various kinds of semiconductor devices such as a solar battery, a photo IC, and a semiconductor memory device can be manufactured using an SOI substrate.

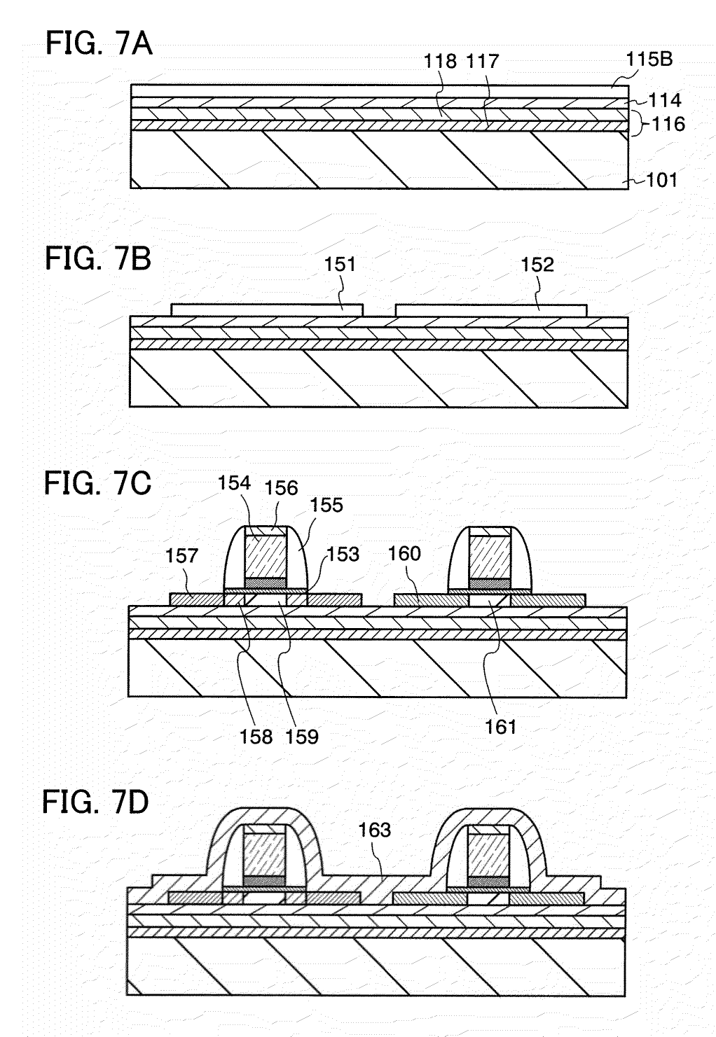

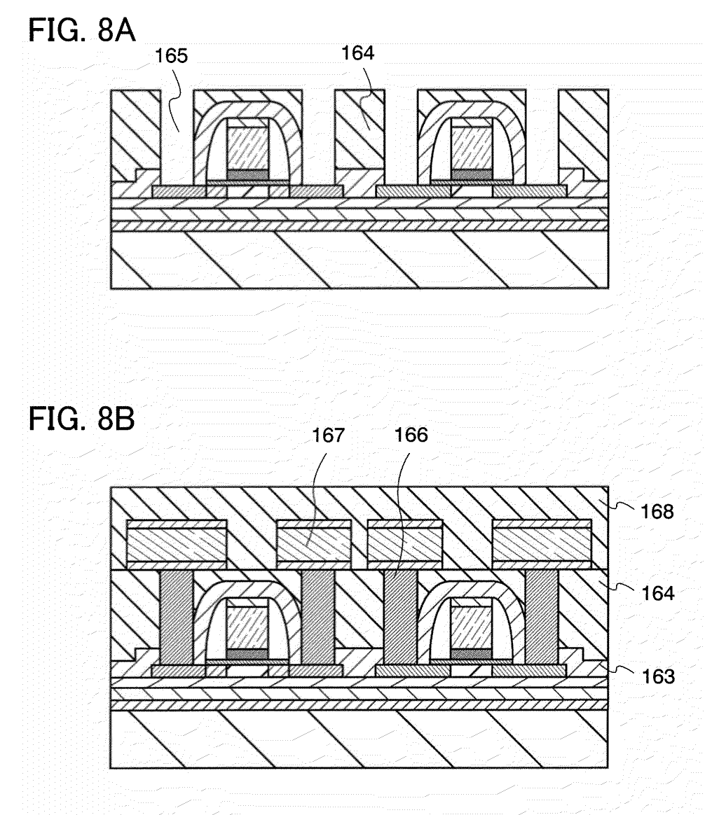

Hereinafter, a method for manufacturing a thin film transistor using an SOI substrate will be described with reference to FIGS. 7A to 7D and FIGS. 8A and 8B. Various kinds of semiconductor devices are formed by combining a plurality of thin film transistors such as transistors each described in this embodiment mode.

FIG. 7A is a cross-sectional view of an SOI substrate. In this embodiment mode, the SOI substrate 132B manufactured by the manufacturing method of Embodiment Mode 2 is used. It is needless to say that an SOI substrate having another structure can be used as well.

To control threshold voltages of TFTs, it is preferable to add a p-type impurity such as boron, aluminum, or gallium or an n-type impurity such as phosphorus or arsenic to the semiconductor layer 115B. The region where the impurity is to be added and the kind of the impurity to be added can be changed as appropriate in accordance with whether an n-channel TFT or a p-channel TFT is to be formed, where a TFT is to be formed, and the like. For example, a p-type impurity can be added to a formation region of an n-channel TFT, and an n-type impurity can be added to a formation region of a p-channel TFT. It is preferable that the addition of the above-described impurity be performed so that the dose amount thereof is equal to or more than 1×10¹² ions/cm² and less than or equal to 1×10¹⁷ ions/cm².

Next, the semiconductor layer 115B of the SOI substrate is separated into island shapes by etching, so that semiconductor layers 151 and 152 are formed (see FIG. 7B). In this embodiment mode, an n-channel TFT is formed using the semiconductor layer 151 and a p-channel TFT is formed using the semiconductor layer 152.

Then, a gate insulating layer 153, a gate electrode 154, a sidewall insulating layer 155, and a silicon nitride layer 156 are formed over each of the semiconductor layers 151 and 152 (see FIG. 7C). The silicon nitride layer 156 is used as a mask in shaping the gate electrode 154 by etching. Note that the gate electrode employs a two-layer structure in this embodiment mode.

Next, impurity addition using the gate electrode 154 as a mask and impurity addition using the gate electrode 154 and the sidewall insulating layer 155 as masks are performed on the semiconductor layers 151 and 152, so that high-concentration n-type impurity regions 157 and low-concentration n-type impurity regions 158 are formed in the semiconductor layer 151 and high-concentration p-type impurity regions 160 are formed in the semiconductor layer 152. Respective regions which overlap with the gate electrodes 154 in the semiconductor layers 151 and 152 become channel formation regions 159 and 161. The high-concentration n-type impurity regions 157 and 160 function as source and drain regions. The low-concentration n-type impurity regions 158 in the n-channel TFT function as LDD regions. After adding the impurities, heat treatment is performed to activate the impurities which are added to the semiconductor layers 151 and 152.

Next, an insulating layer 163 containing hydrogen is formed (see FIG. 7D). After the formation of the insulating layer 163, heat treatment at a temperature equal to or higher than 350° C. and equal to or lower than 450° C. is performed, so that hydrogen contained in the insulating layer 163 is diffused into the semiconductor layers 151 and 152. The insulating layer 163 can be formed by stacking silicon nitride or silicon nitride oxide by a plasma CVD method at a process temperature of equal to or lower than 350° C. By supplying hydrogen for the semiconductor layers 151 and 152, defects at an interface between the semiconductor layer 151 and the gate insulating layer 153 and at an interface between the semiconductor layer 152 and the gate insulating layer 153 can be effectively reduced.

After that, an interlayer insulating layer 164 is formed (see FIG. 8A). As the interlayer insulating layer 164, a film formed of an inorganic material such as BPSG (boron phosphorus silicon glass) or an organic resin film formed of, typically, polyimide can be used. Contact holes 165 are formed in the interlayer insulating layer 164.

Next, wirings and the like are formed (See FIG. 8B). Contact plugs 166 are formed in the contact holes 165. As the contact plug 166, tungsten silicide is formed by a chemical vapor deposition method using a WF₆ gas and a SiH₄ gas to fill the contact hole 165. Alternatively, tungsten may be formed by hydrogen reduction of WF₆ to fill the contact holes 165. After that, wirings 167 are formed in accordance with the contact plugs 166. The wirings 167 each employ a three-layer structure in which a conductive film formed of aluminum or aluminum alloy is sandwiched between metal films of molybdenum, chromium, titanium, or the like which function as barrier metal. An interlayer insulating film 168 is formed over the wirings 167. The wirings 167 may be provided as appropriate, and another wiring layer may be further formed thereover to form a multilayer wiring structure. In this case, a damascene process such as a single-damascene process or a dual-damascene process can be employed.

In this manner, thin film transistors each using an SOI substrate can be manufactured. A semiconductor layer in an SOI substrate is a single-crystal semiconductor layer in which there are few crystal defects and the interface state density between the semiconductor layer and the gate insulating layer 153 is reduced. Further, the surface thereof is planarized and the thickness thereof is reduced to 100 nm or less. Accordingly, thin film transistors with excellent characteristics such as low driving voltage, high electron field-effect mobility, and a low subthreshold value can be formed over the base substrate 101. Further, high performance transistors with less variation in characteristics can be formed over the same substrate. That is, by using the SOI substrate described each of Embodiment Modes 1 to 3, variation in important characteristics as transistor characteristics, such as threshold voltage or mobility can be suppressed and the characteristics can be improved.

By forming a semiconductor element using the SOI substrate according to any of the methods of Embodiment Modes 1 to 3 as described above, a high-value-added semiconductor device can be manufactured at low cost. Hereinafter, a specific mode of a semiconductor device will be described with reference to drawings.

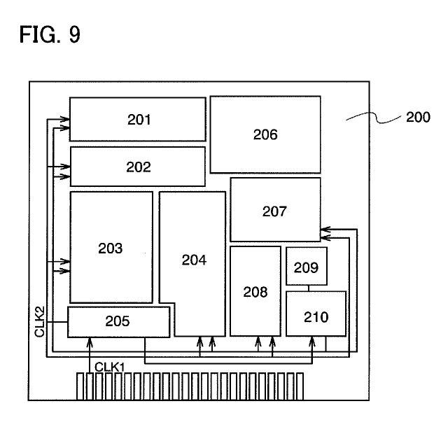

First, as an example of the semiconductor device, a microprocessor will be described. FIG. 9 is a block diagram showing a structure example of a microprocessor 200.

This microprocessor 200 has an arithmetic logic unit (ALU) 201, an ALU controller 202, an instruction decoder 203, an interrupt controller 204, a timing controller 205, a register 206, a register controller 207, a bus interface (Bus I/F) 208, a read-only memory (ROM) 209, and a memory interface (ROM I/F) 210.

An instruction input to the microprocessor 200 through the bus interface 208 is input to the instruction decoder 203 and decoded therein, and then input to the ALU controller 202, the interrupt controller 204, the register controller 207, and the timing controller 205. The ALU controller 202, the interrupt controller 204, the register controller 207, and the timing controller 205 perform various controls based on the decoded instruction.

Specifically, the ALU controller 202 generates signals for controlling the operation of the ALU 201. Further, while the microprocessor 200 is executing a program, the interrupt controller 204 processes an interrupt request from an external input/output device or a peripheral circuit based on its priority or a mask state. The register controller 207 generates an address of the register 206, and reads and writes data from and to the register 206 in accordance with the state of the microprocessor 200. The timing controller 205 generates signals for controlling timing of operation of the ALU 201, the ALU controller 202, the instruction decoder 203, the interrupt controller 204, and the register controller 207.

For example, the timing controller 205 is provided with an internal clock generator for generating an internal clock signal CLK2 based on a reference clock signal CLK1, and supplies the internal clock signal CLK2 to the above-described various circuits. Note that the microprocessor 200 shown in FIG. 9 is only an example in which the structure is simplified, and actually, a microprocessor may have various structures depending on the uses.

The microprocessor 200 can achieve not only an increase in processing speed but also a reduction in power consumption because an integrated circuit is formed using a single-crystal semiconductor layer with uniform crystal orientation (an SOI layer) which is bonded to a substrate having an insulating surface or an insulating substrate.

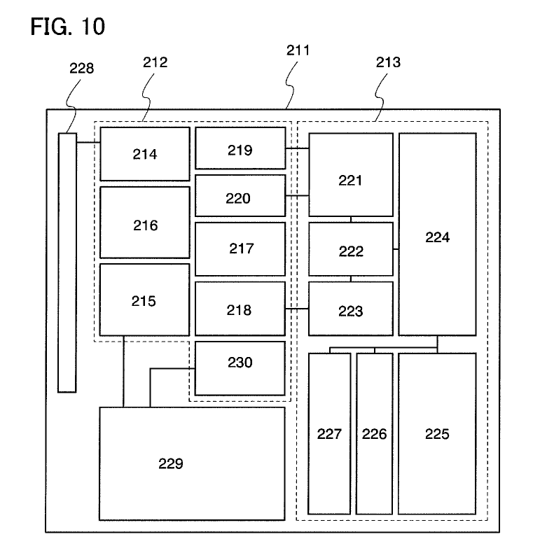

Next, an example of a semiconductor device provided with a function of transmitting and receiving data wirelessly and an arithmetic function will be described. FIG. 10 is a block diagram showing a structure example of such a semiconductor device. The semiconductor device shown in FIG. 10 can be considered as a computer which operates by performing signal transmission and reception to and from an external device by wireless communication (hereinafter referred to as an ‘RFCPU’).

An RFCPU 211 includes an analog circuit portion 212 and a digital circuit portion 213 as shown in FIG. 10. The analog circuit portion 212 includes a resonance circuit 214 with a resonance capacitor, a rectifier circuit 215, a constant voltage circuit 216, a reset circuit 217, an oscillator circuit 218, a demodulator circuit 219, and a modulator circuit 220. The digital circuit portion 213 includes an RF interface 221, a control register 222, a clock controller 223, a CPU interface 224, a central processing unit 225, a random-access memory 226, and a read-only memory 227.

The operation of the RFCPU 211 will be roughly described. The resonance circuit 214 generates an induced electromotive force based on a signal received by an antenna 228. The induced electromotive force is stored in a capacitor portion 229 through the rectifier circuit 215. This capacitor portion 229 is preferably formed using a capacitor such as a ceramic capacitor or an electric double-layer capacitor. The capacitor portion 229 is not necessarily formed over the same substrate as the RFCPU 211 and the capacitor portion 229 can be attached as a different component to the substrate having an insulating surface which is included in the RFCPU 211.

The reset circuit 217 generates a signal for resetting to initialize the digital circuit portion 213. For example, a signal that rises after an increase in power supply voltage is generated as the reset signal. The oscillator circuit 218 changes the frequency and duty ratio of a clock signal in response to a control signal generated by the constant voltage circuit 216. The demodulator circuit 219 is a circuit which demodulates a received signal, and the modulator circuit 220 is a circuit which modulates data that is to be transmitted.

For example, the demodulator circuit 219 includes a low pass filter, and binarizes a received signal of an amplitude shift keying (ASK) system based on a change in amplitude of the signal. The modulation circuit 220 transmits transmission data by changing the amplitude of a transmission signal of an amplitude shift keying (ASK) system. Therefore, the modulation circuit 220 changes the resonance point of the resonance circuit 214, thereby changing the amplitude of a communication signal.

The clock controller 223 generates a control signal for changing the frequency and duty ratio of a clock signal in accordance with a power supply voltage or current consumption of the central processing unit 225. The power supply voltage is monitored by the power supply control circuit 230.

A signal input from the antenna 228 to the RFCPU 211 is demodulated by the demodulator circuit 219 and then decomposed into a control command, data, and the like by the RF interface 221. The control command is stored in the control register 222. The control command includes reading of data stored in the read-only memory 227, writing of data to the random-access memory 226, an arithmetic instruction to the central processing unit 225, and the like.

The central processing unit 225 accesses the read-only memory 227, the random-access memory 226, and the control register 222 via the CPU interface 224. The interface 224 has a function of generating an access signal for any of the read-only memory 227, the random-access memory 226, and the control register 222 based on an address the central processing unit 225 requests.

As an arithmetic method of the central processing unit 225, a method may be employed in which the read-only memory 227 stores an operating system (OS) in advance and a program is read and executed at the time of starting operation. Alternatively, a method may be employed in which a circuit dedicated to arithmetic is formed as an arithmetic circuit and an arithmetic processing is conducted using hardware. In a method in which both hardware and software are used, part of processing can be conducted by a circuit dedicated to arithmetic, and the other part of the arithmetic processing can be conducted by the central processing unit 225 using a program.

The RFCPU 211 can achieve not only an increase in processing speed but also a reduction in power consumption because an integrated circuit is formed using a single-crystal semiconductor layer with uniform crystal orientation (an SOI layer) which is bonded to a substrate having an insulating surface or an insulating substrate. Accordingly, even when the capacitor portion 229 which supplies electric power is miniaturized, long-term operation is ensured.

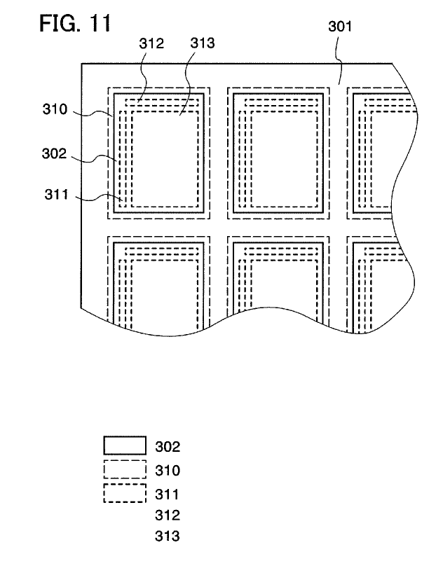

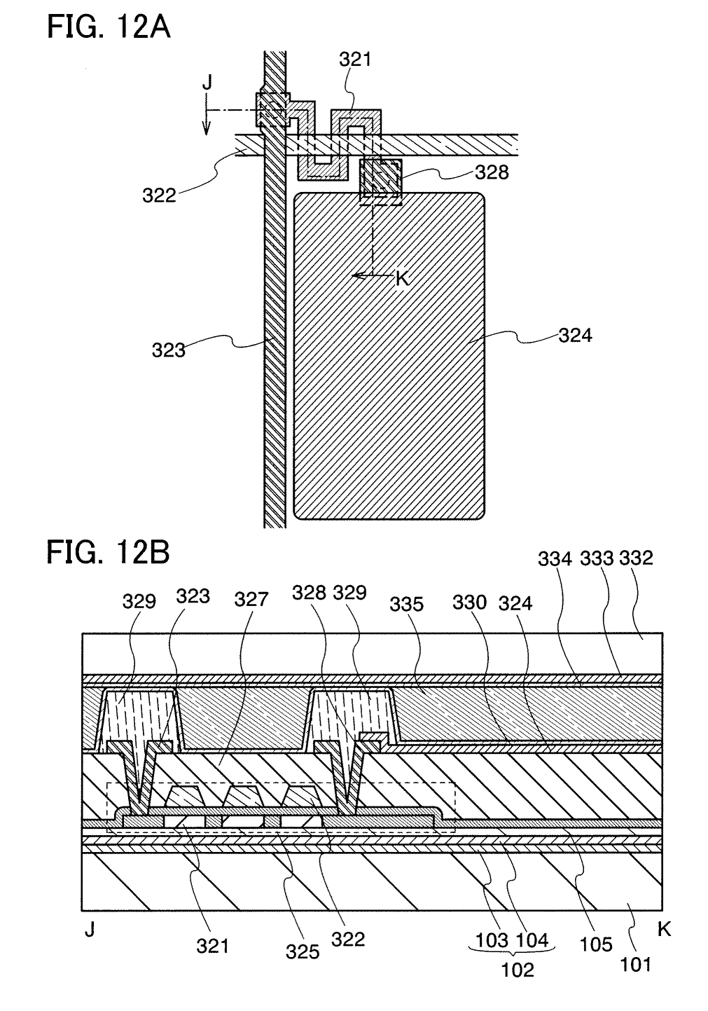

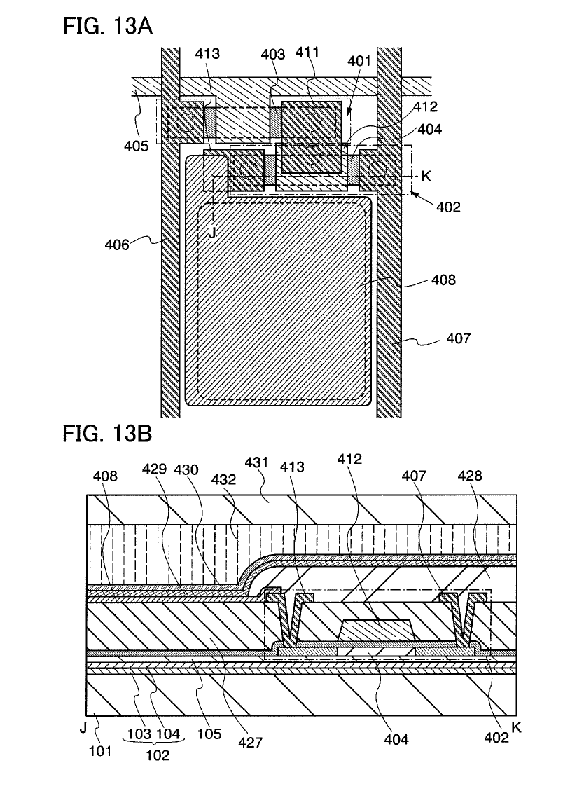

Next, as the semiconductor device of the present invention, a display device will be described with reference to FIG. 11, FIGS. 12A and 12B, and FIGS. 13A and 13B.

A large-area glass substrate called mother glass over which a display panel is manufactured can be used as a base substrate of an SOI substrate. FIG. 11 is a front view of an SOI substrate in which mother glass is used as the base substrate 101.

Semiconductor layers 302 which are separated from a plurality of semiconductor substrates are attached to one mother glass 301. In order to divide the mother glass 301 to provide a plurality of display panels, the semiconductor layers 302 are preferably bonded in display panel formation regions 310. Each of the display panels includes a scanning line driver circuit, a signal line driver circuit, and a pixel portion. Therefore, each of the semiconductor layers 302 is bonded to the region where the above-described driver circuits are formed (a scanning line driver circuit formation region 311, a signal line driver circuit formation region 312, and a pixel formation region 313) in each of the display panel formation regions 310.

FIGS. 12A and 12B are drawings for showing a liquid crystal display device manufactured using the SOI substrate shown in FIG. 11. FIG. 12A is a plan view of a pixel of the liquid crystal display device and FIG. 12B is a cross-sectional view along cutting line J-K of FIG. 12A.

In FIG. 12A, a semiconductor layer 321 is a layer formed of the semiconductor layer 302 which is attached to the mother glass 301 and included in a TFT of the pixel. In this embodiment mode, the SOI substrate manufactured by the method of Embodiment Mode 3 is used as the SOI substrate. As shown in FIG. 12B, the substrate in which the insulating layer 102, the bonding layer 105, and the semiconductor layer are stacked over the base substrate 101 is used. The base substrate 101 is the mother glass 301 which has been divided. As shown in FIG. 12A, the pixel includes the semiconductor layer 321, a scanning line 322 which intersects the semiconductor layer 321, a signal line 323 which intersects the scanning line 322, a pixel electrode 324, and an electrode 328 which electrically connects the pixel electrode 324 and the semiconductor layer 321 to each other.

As shown in FIG. 12B, a TFT 325 of the pixel is formed over the bonding layer 105. A gate electrode of the TFT 325 is included in the scanning line 322, and a source electrode or a drain electrode of the TFT 325 is included in the signal line 323. The signal line 323, the pixel electrode 324, and the electrode 328 are provided over the interlayer insulating film 327. Columnar spacers 329 are formed over the interlayer insulating film 327, and an orientation film 330 is formed covering the signal line 323, the pixel electrode 324, the electrode 328, and the columnar spacers 329. A counter substrate 332 is provided with a counter electrode 333 and an orientation film 334 which covers the counter electrode 333. The columnar spacers 329 are formed to keep the gap between the base substrate 101 and the counter substrate 332. A liquid crystal layer 335 is formed in spaces formed by the columnar spacers 329. At portions where the semiconductor layer 321 is connected to the signal line 323 and the electrode 328, steps are generated in the interlayer insulating film 327 by the formation of the contact holes, and the steps disorder orientation of liquid crystals of the liquid crystal layer 335. Therefore, the columnar spacers 329 are formed at the steps to prevent the disorder of the orientation of liquid crystals.

Next, an electroluminescent display device (hereinafter referred to as an EL display device) will be described. FIGS. 13A and 13B are drawings showing an EL display device manufactured using the SOI substrate shown in FIG. 11. FIG. 13A is a plane view of a pixel of the EL display device, and FIG. 13B is a cross-sectional view of the pixel.

In FIGS. 13A and 13B, a selection transistor 401 and a display control transistor 402 each including a TFT are formed in the pixel. A semiconductor layer 403 of the selection transistor 401 and a semiconductor layer 404 of the display control transistor 402 are layers formed by processing the semiconductor layer 302 of the SOI substrate of FIG. 11. The pixel includes a scanning line 405, a signal line 406, a current supply line 407, and a pixel electrode 408. Each pixel is provided with a light-emitting element having a structure in which a layer including an electroluminescent material (hereinafter this layer is referred to as an EL layer) is sandwiched between a pair of electrodes in an EL display device. One electrode of the light-emitting element is the pixel electrode 408.

In the selection transistor 401, a gate electrode is included in the scanning line 405, one of a source electrode or a drain electrode is included in the signal line 406, and the other thereof is formed as an electrode 411. In the display control transistor 402, a gate electrode 412 is electrically connected to the electrode 411, one of a source electrode or a drain electrode is formed as an electrode 413 which is electrically connected to the pixel electrode 408, and the other thereof is included in the current supply line 407.

Note that, as the SOI substrate, the substrate manufactured by the method of Embodiment Mode 3 is used. Similarly to FIG. 12B, the insulating layer 102, the bonding layer 105, and the semiconductor layer 115B are stacked over the base substrate 101. The base substrate 101 is the mother glass 301 which has been divided.

As shown in FIG. 13B, an interlayer insulating film 427 is formed to cover the gate electrode 412 of the display control transistor 402. Over the interlayer insulating film 427, the signal line 406, the current supply line 407, the electrode 411, the electrode 413, and the like are formed. Further, over the interlayer insulating film 427, the pixel electrode 408 which is electrically connected to the electrode 413 is formed. A peripheral portion of the pixel electrode 408 is surrounded by a bank layer 428 having an insulating property. An EL layer 429 is formed over the pixel electrode 408, and a counter electrode 430 is formed over the EL layer 429. A counter substrate 431 is provided as a reinforcing plate, and is fixed to the base substrate 101 by a resin layer 432. A plurality of the pixels shown in FIGS. 13A and 13B is arranged in matrix in the pixel portion of the EL display device.

The grayscale of an EL display device is controlled by either a current drive method by which the luminance of a light-emitting element is controlled by current or a voltage drive method by which the luminance of a light-emitting element is controlled by voltage. The current drive method is difficult to adapt when transistors have characteristics which are largely different between pixels, and therefore, a compensation circuit for compensating variation in characteristics is necessary. By using the SOI substrate of the present invention, there is less variation in characteristics of the selection transistor 401 and the display control transistor 402 between pixels; therefore, the current driving method can be employed.

As shown in FIGS. 12A and 12B and FIGS. 13A and 13B, an SOI substrate can be manufactured using a mother glass for manufacturing a display device, and a display device can be manufactured using the SOI substrate. Further, since the microprocessor as shown in FIG. 9 or 10 can also be formed using this SOI substrate, a display device can be provided with a computer function. Further, a display device capable of data input and output without contact can be manufactured as well.

That is, by using the SOI substrate of the present invention, various electric appliances can be manufactured. The electric appliances include cameras such as video cameras and digital cameras, navigation systems, audio reproducing devices (e.g., car audios or audio components), computers, game machines, portable information terminals (e.g., mobile computers, mobile phones, portable game machines, or electronic books), and image reproducing devices provided with a recording medium (specifically, devices that can reproduce image data recorded in a recording medium such as a digital versatile disk (DVD) and are equipped with a display device capable of displaying the image).

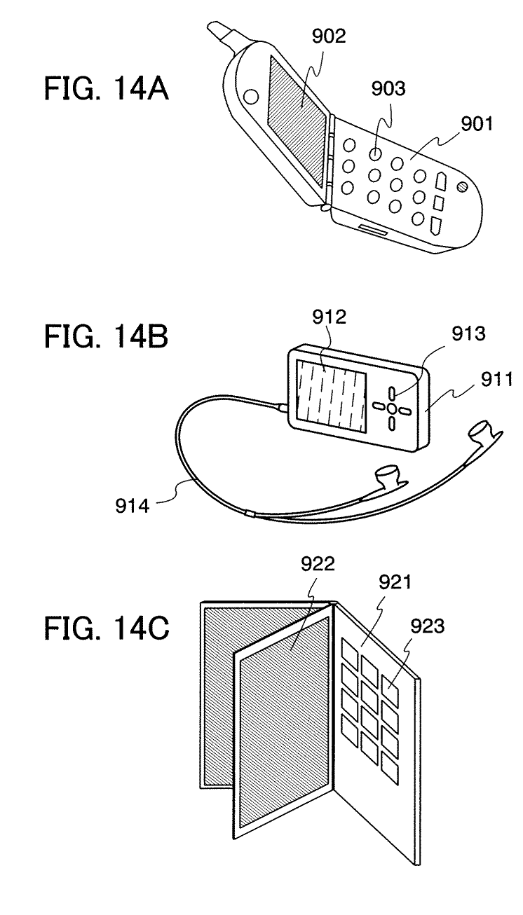

With reference to FIG. 14A to 14C, specific modes of the electric appliances will be described. FIG. 14A is an external view showing an example of a mobile phone 901. This mobile phone 901 includes a display portion 902, operation switches 903, and the like. By employing the liquid crystal display device shown in FIGS. 12A and 12B or the EL display device shown in FIGS. 13A and 13B for the display portion 902, the display portion 902 with less display variation and high image quality can be provided. The semiconductor device formed using an SOI substrate of the present invention can also be applied to a microprocessor, a memory, or the like included in the mobile phone 901.

FIG. 14B is an external view illustrating a structure of a digital player 911. The digital player 911 includes a display portion 912, an operation portion 913, an earphone 914, and the like. Instead of the earphone 914, a headphone or a wireless earphone can be used. By employing the liquid crystal display device shown in FIGS. 12A and 12B or the EL display device shown in FIGS. 13A and 13B for the display portion 912, high-definition images and many pieces of character information can be displayed even when the screen size is about 0.3 to 2 inches. Further, the semiconductor device formed using an SOI substrate of the present invention can be applied to a memory portion which stores music information or a microprocessor which are included in the digital player 911.

Further, FIG. 14C is an external view of an electronic book 921. This electronic book 921 includes a display portion 922 and an operation switch 923. The electronic book 921 may incorporate a modem or may incorporate the RFCPU shown in FIG. 10 so that information can be communicated wirelessly. By employing the liquid crystal display device shown in FIGS. 12A and 12B or the EL display device shown in FIGS. 13A and 13B for the display portion 922, display can be performed with high image quality. In the electronic book 921, the semiconductor device formed using an SOI substrate of the present invention can be applied to a memory portion which stores information or a microprocessor which allows the electronic book 921 to operate.

This embodiment mode can be combined with any of Embodiment Modes 1 to 4 as appropriate.

### Embodiment 1

In this embodiment, as an example of the semiconductor device of the present invention, an RFID tag provided with real-time location systems (RTLS) will be described. RTLS by which the location of an object can be found can reduce the time taken to search an object and can be used for various uses by combination with other information (e.g., hazardous material management). In this point, there is an advantage over a conventional technology which discriminates whether or not an object exists. Note that, with a passive-type RFID in which there is no need of a power supply wiring, a semipermanent RTLS function can be obtained.

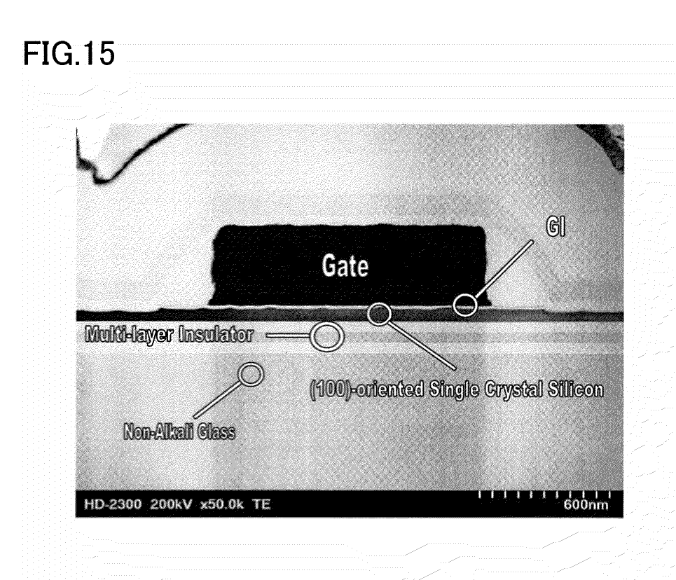

In order to realize RTLS, enough communication distance is needed. When low temperature polysilicon (LTPS) is used, however, the rectified voltage is low due to existence of crystal grain boundaries and the communication distance is not enough. According to the present invention, a single-crystal-silicon layer having a (100) plane as a main surface is formed over a non-alkali glass substrate, so that the efficiency of a rectifier circuit can be improved. As a result of this, RTLS can be achieved. A cross-sectional photograph of a TFT using a single-crystal-silicon layer having a (100) plane as a main surface, manufactured in this embodiment is FIG. 15. It can be seen that a single-crystal-silicon layer is formed over a non-alkali glass substrate with an insulating layer interposed therebetween.

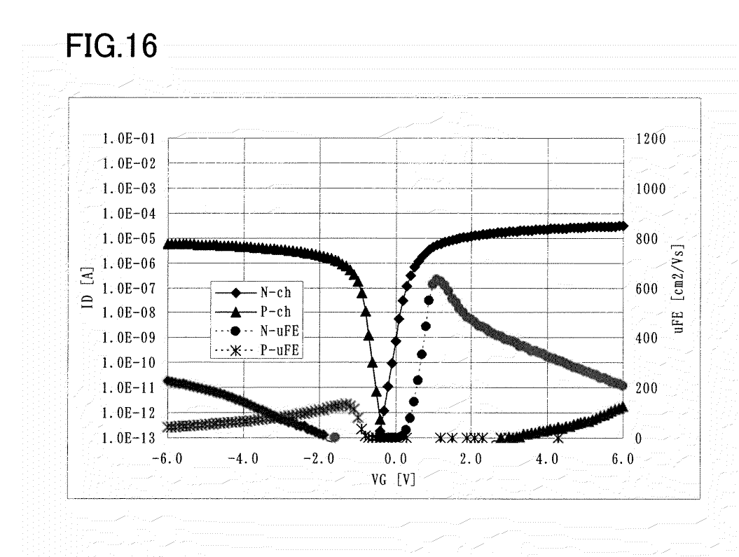

In FIG. 16, gate voltage vs. drain current (VG-ID) characteristics of TFTs and gate voltage vs. mobility (VG-μFE) characteristics of the same are shown. Note that each parameter of the TFTs was as follows:

Channel length: 10 μm

Thickness of gate insulating layer: 20 nm

Thickness of single-crystal-silicon layer: 100 nm

Note that, as a countermeasure against off current (Ioff), an LDD (lightly-doped-drain) structure using a sidewall was employed. The electron field-effect mobility of an n-channel TFT was 635 cm²/Vs, and the electron field-effect mobility of a p-channel TFT was 134 cm²/Vs.

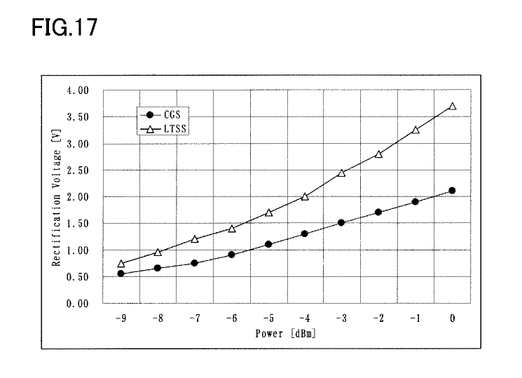

In FIG. 17, comparison of rectification voltage of low temperature polysilicon (LTPS) and single crystal silicon over a glass substrate is shown. With the single crystal silicon over a glass substrate, higher rectification voltage than the low temperature polysilicon (LTPS) was able to be obtained.

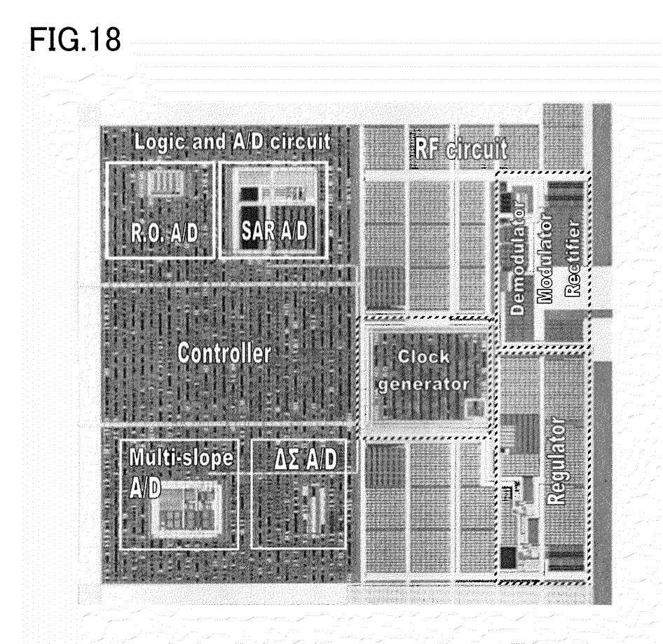

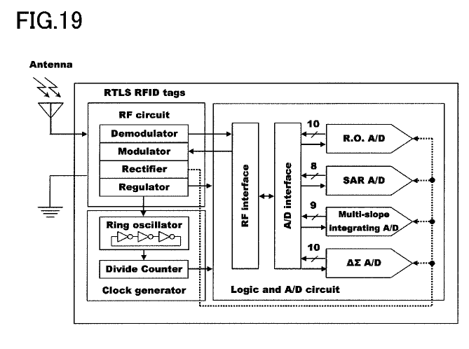

The RTLS-RFID tag formed as a sample in this embodiment was manufactured by a process in which the wiring width and the wiring interval both are 0.8 μm. The number of transistors was 24000 and the die size was 5 mm×5 mm. A photograph of the RTLS-RFID tag (chip) and a block diagram of the same are FIGS. 18 and 19, respectively.

A carrier wave of 915 MHz capable of long-distance communication in principle was used in order to maximize the RTLS function in this embodiment. However, the present invention is not limited to this.

Note that, in this embodiment, because correct clock generation which is independent of voltage and temperature and an estimate of signal arrival bearing are difficult, an RSSI (receive signal strength indicator) system was selected to realize the RTSL function. An RSSI system is a system utilizing that the electric-field intensity depends on the distance. Distance detection can be realized by provision of an A/D circuit as a peripheral circuit (peripheral) of the RFID.

A communication standard of the RTLS-RFID tag in this embodiment was partially based on Auto-ID Center Class I Region 1 (North America). Further, in order to measure the location with high accuracy, sensitivity distribution and power consumption difference in four kinds of A/D circuits were utilized. The RTLS-RFID tag in this embodiment includes an RF circuit including a power source circuit, a demodulator circuit, and a modulator circuit, a clock generator, an RF interface, an AD interface, four kinds of A/D circuits, and/or the like. The clock generator adopted digital control in order to generate clock signals which are independent of variation of TFTs and have stable frequencies. The RF interface has functions of parallel conversion of received signals which are serial signals, parity check, change of the order of data, and the like.

In this embodiment, the following four kinds of A/D circuits having different architecture were used in consideration of change in electric power by the communication distance or A/D conversion by a small amount of electric power. A ring-oscillator A/D (R.O.A/D) had 10-bit resolution and utilized characteristics of changing the oscillation frequency depending on a voltage value. Each ring-oscillator is oscillated by using, as a power source voltage, an input voltage which is changed by the received electric power intensity and a reference voltage, and the numbers of toggles of the ring-oscillators are each counted and compared with each other. A successive approximation A/D (SAR A/D) had 8-bit resolution and included a comparator, a DAC, an SAR, and a logic control portion. The DAC outputs a voltage by combination of resistance and a reference voltage so that the total obtained by weighting steps in which one-bit conversion is performed in one step is obtained. A multi-slope integrating A/D had 9-bit resolution and included an analog integrator, a comparator, and a counter. The input voltage is charged for a certain period in a capacitor and is integrated. After that, the counter is reset and the counter is operated for a period in which reverse integration is performed by electric discharge. A sigma-delta A/D (ΣΔA/D) had 10-bit resolution and included a cumulative adder (Σ) and a difference device (Δ). Oversampling by high-speed clocks is generally performed; however, sampling 1000 times was performed using low-speed clocks because there was little fluctuation of an input voltage in the circuit in this embodiment.

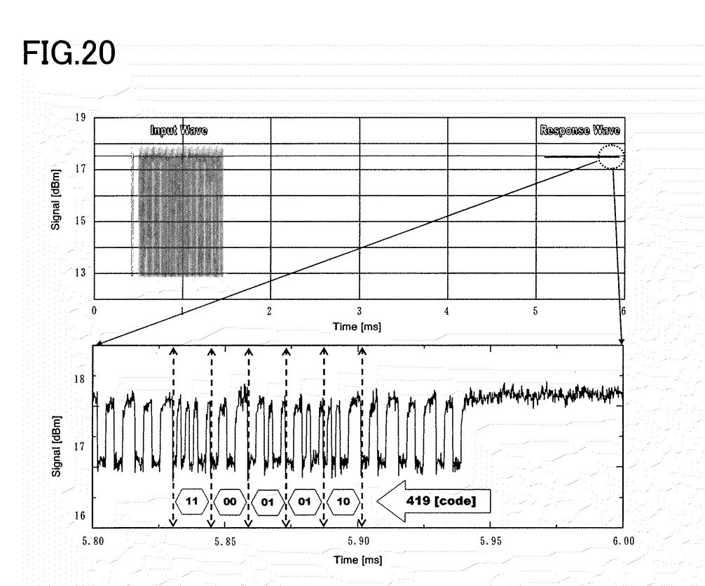

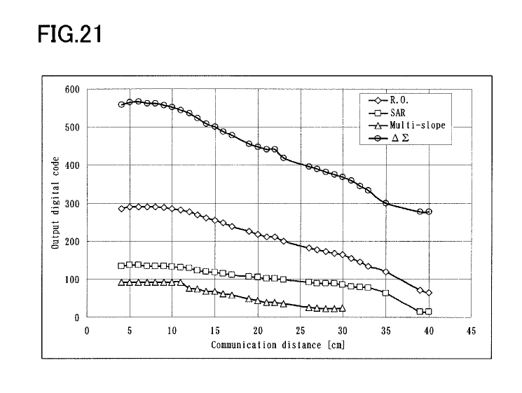

FIGS. 20 and 21 show results of radio measurement of the RTLS-RFID tag of this embodiment. The measurement was performed by receiving a reply signal from the RTLS-RFID tag with the use of a spectrum analyzer. A reply signal waveform is shown in FIG. 20 and a relationship of communication distance vs. output digital code is shown in FIG. 21. A communication distance resolution 5 cm/1 code corresponding to a performance target value was satisfied in the communication distances from 11 cm to 40 cm. Further, it was confirmed that the four kinds of A/D circuits each have a communication distance resolution of 2 cm/1 code or less as an actual measurement value and can obtain performance of 2 mm/1 code to 5 mm/1 code.

In this embodiment, the RTLS-RFID tag system was realized as the semiconductor device of the present invention. By using single crystal silicon over a glass substrate as described above, crystal grain boundaries do not affect, and thus, rectification efficiency is improved.

This embodiment can be combined with any of Embodiment Modes 1 to 5 as appropriate.

### Embodiment 2

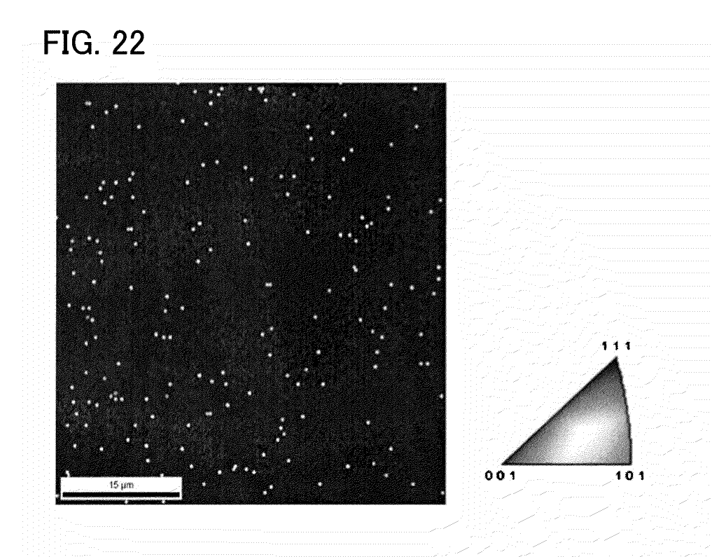

In this embodiment, a CPU using a single-crystal-silicon TFT formed over a glass substrate will be described as an example of the semiconductor device of the present invention. First, an analysis result of crystal orientation of single crystal silicon over a glass substrate by EBSP (electron backscatter diffraction pattern) is shown in FIG. 22. It can be confirmed that crystals are orientated in the (100) direction in almost the whole region of a plane. That is, it can be seen that a single-crystal-silicon layer is formed over a glass substrate.

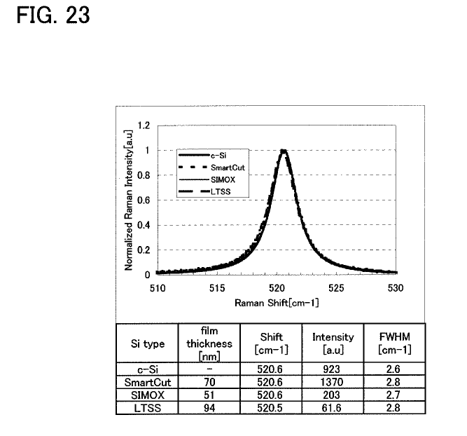

Raman spectra of the following are shown in FIG. 23: single crystal silicon each in conventional SOI substrates (a substrate formed by Smart-Cut technology and a SIMOX substrate); bulk silicon (c-Si); and the single crystal silicon formed over a glass substrate by a low-temperature process of the present invention, of the present invention (LTSS: low temperature single crystal silicon). The single crystal silicon formed over a glass substrate by a low-temperature process has almost the same peak position as the bulk silicon or the other single crystal silicon each in the SOI substrate and has a similar full width at half maximum to the bulk silicon or the other single crystal silicon each in the SOI substrate. Thus, it can be found that the single crystal silicon formed over a glass substrate has a very close crystallinity to the bulk silicon.

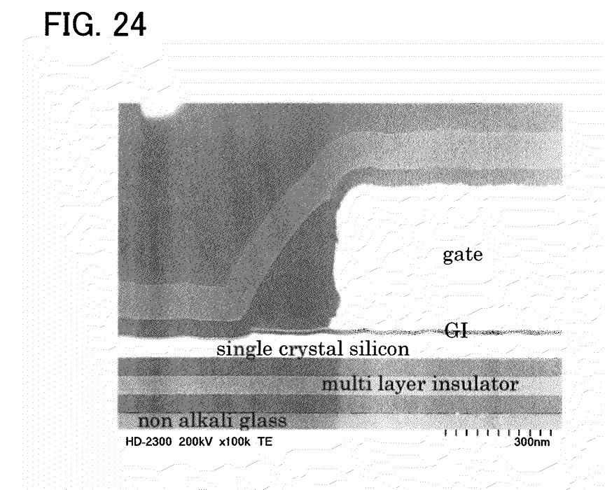

FIG. 24 is a cross-sectional photograph of the single-crystal-silicon TFT formed over a glass substrate, of the present invention. The maximum temperature of a process in this embodiment was 600° C. That is, a conventional production line for low temperature polysilicon TFTs can be used as it is to manufacture a single-crystal-silicon TFT over a glass substrate. Further, planarization is performed not by CMP treatment but also laser beam irradiation, and therefore, an existing production line can be used without a significant change, which is desirable. According to the present invention, an LSI can be formed over a large-area glass substrate. That is, production cost can be reduced, and therefore, the present invention is suited for mass production.

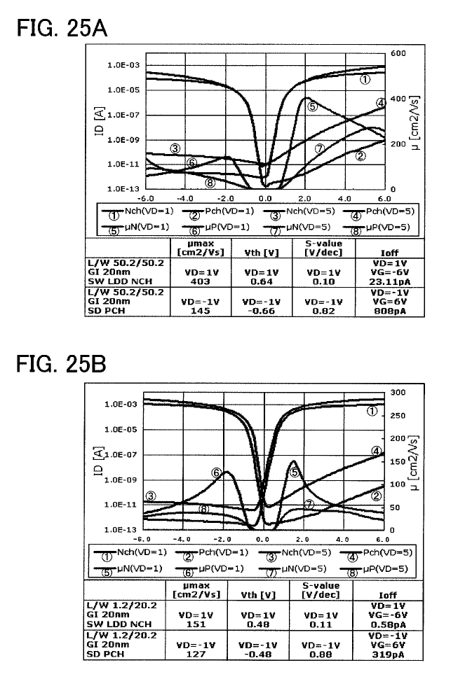

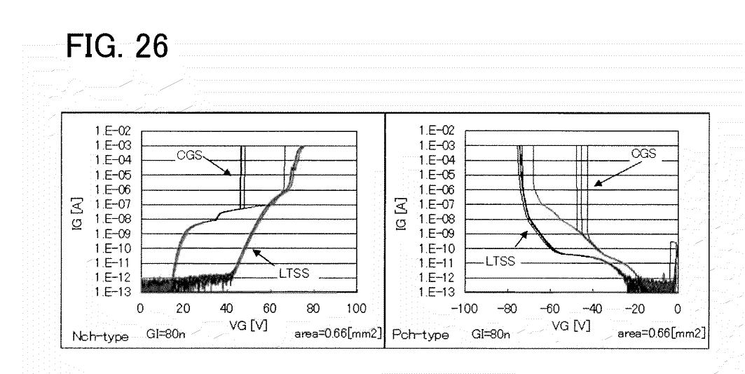

VG-ID (gate voltage-drain current) curves, VG-μ (gate voltage-mobility) curves, and TFT characteristics tables of TFTs (n-channel TFTs and p-channel TFTs) of this embodiment are shown in FIGS. 25 and 26. Note that, in each graph, the horizontal axis indicates VG and the vertical axis indicates ID (on the left) or μ (on the right). In each of the TFT characteristics tables, characteristics of each n-channel TFT are shown in the upper stage and characteristics of each p-channel TFT are shown in the lower stage. Note that channel length L and channel width W of each TFT whose characteristics are shown in FIG. 25A were L/W=50.2 M/50.2 μm, and channel length L and channel width W of each TFT whose characteristics are shown in FIG. 25B were L/W=1.2 μm/20.2 μm. In either TFT, the thickness of a gate insulating layer was 20 nm and the thickness of a single-crystal-silicon layer was 120 nm. It is found from FIGS. 25A and 25B that TFTs having superior characteristics are formed.

Characteristics of gate resistance to pressure of capacitor TEGs each formed using the TFT of this embodiment are shown in FIG. 26. For comparison, characteristics of gate resistance to pressure of capacitor TEGs each formed using low temperature polysilicon are also shown in the drawing. Note that, in this embodiment, characteristics of capacitor TEGs each manufactured using CGS (continuous grain silicon) as an example of the low temperature polysilicon is shown. Here, the horizontal axis indicates gate voltage (VG) and the vertical axis indicates current flowing through a gate electrode (IG). The current flowing through a gate electrode is the same or substantially the same as current flowing through a gate insulating film; therefore, the characteristics of resistance to breakdown voltage of the gate insulating film can be found out from FIG. 26. From FIG. 26, it is found that the resistance to breakdown voltage of the gate insulating film is higher in the TFT of the present invention than in the low temperature polysilicon. This suggests that surface roughness of the single crystal silicon in this embodiment is reduced enough.

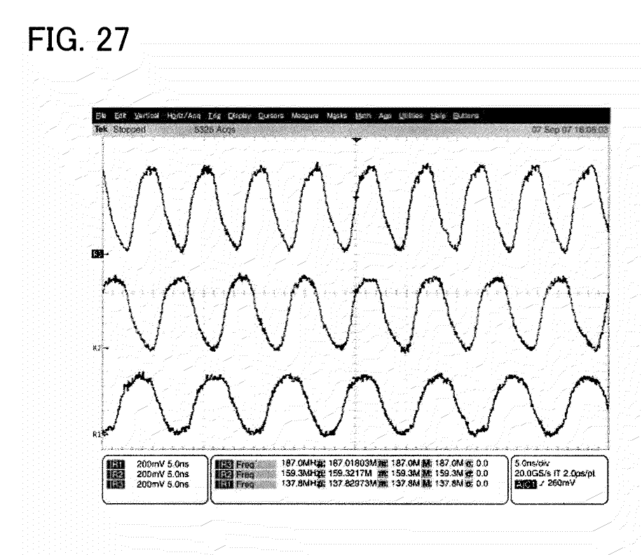

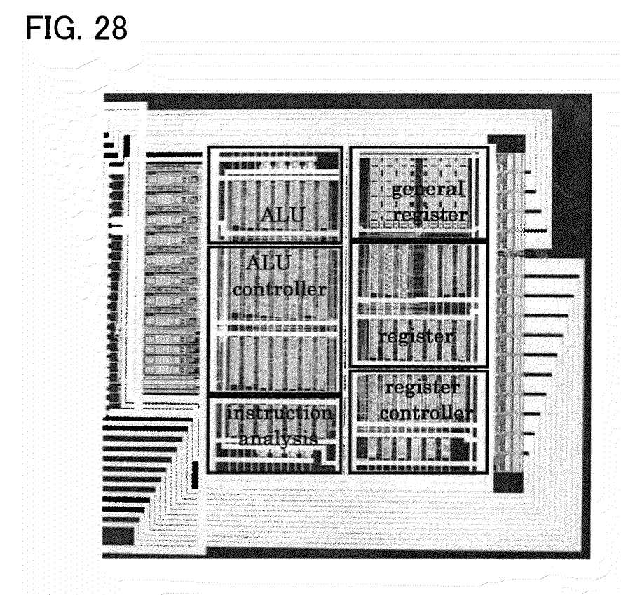

A waveform of a 9-stage ring oscillator including the TFT of this embodiment is shown in FIG. 27. FIG. 28 is a photograph of a CPU manufactured in this embodiment. The CPU includes an SRAM, an ALU, a control circuit, and the like.

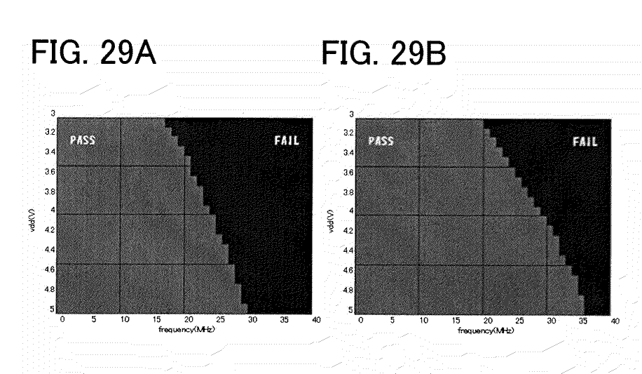

FIG. 29A shows a shmoo plot of a CPU manufactured using CGS, and FIG. 29B shows a shmoo plot of a CPU manufactured using the single crystal silicon in this embodiment. Here, the horizontal axis indicates an operation frequency and the vertical axis indicates a power source voltage. For comparison, they were manufactured using the same mask pattern. From FIGS. 29A and 29B, it is found that the operation frequency of the CPU manufactured using the single crystal silicon in this embodiment is higher than that of the CPU manufactured using CGS.

This embodiment can be combined with any of Embodiment Modes 1 to 5 and Embodiment 1 as appropriate.

### Embodiment 3

In this embodiment, surface roughness of the SOI substrate of Embodiment Mode 1 was measured. Note that, as a semiconductor substrate, a single-crystal-silicon substrate having a (100) plane as a main surface was used. In this embodiment, surface roughness of a single-crystal-silicon layer whose planarity is improved with a XeCl excimer laser with a wavelength of 308 nm, a pulse width of 25 nsec, and a repetition frequency of 30 Hx was measured.

The planarity of the surface of the single-crystal-silicon layer and the crystallinity thereof can be analyzed by, for example, observation with an optical microscope, an atomic force microscope (AFM), or a scanning electron microscope (SEM), observation of an electron back scatter diffraction pattern (EBSP), Raman spectroscopy, or the like.

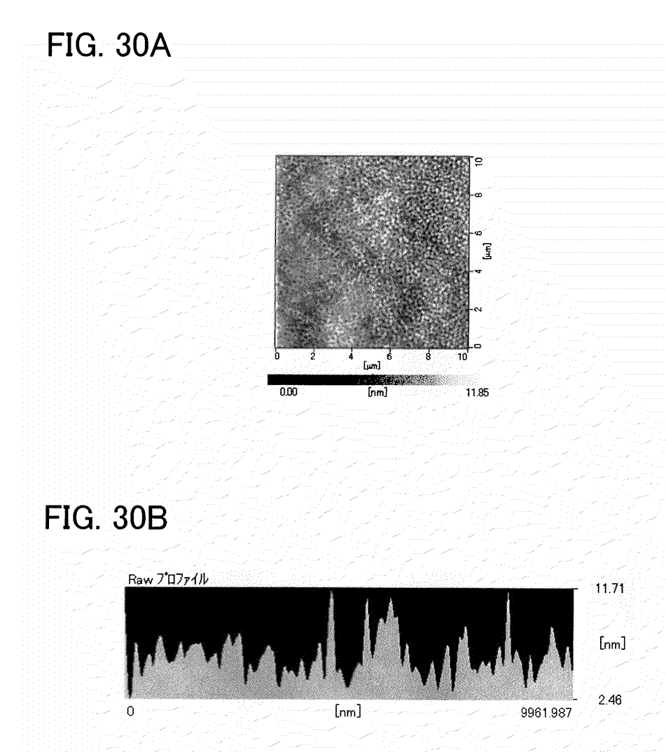

In this embodiment, observation results with AFM were described. An example of a profile of a plane and a cross section of the single-crystal-silicon layer of the present invention, observed with AFM is shown in FIGS. 30A and 30B. FIG. 30A is an observation image of the surface and FIG. 30B shows a profile of the cross section. The surface roughness calculated based on data of FIGS. 30A and 30B and the like was as follows:

Ra: 1.5 nm

RMS: 1.9 nm

P-V: 18.0 nm

For confirmation of the effect of laser beam irradiation, measurement was also performed in a similar manner on the SOI substrate before the laser beam irradiation. Further, measurement was also performed in a similar manner by changing the atmosphere at the time of the laser beam irradiation. The measurement results thereof are all shown in Table 1.

### (Table 1)

Ra of the silicon layer before the laser beam irradiation was equal to or more than 7 nm and RMS thereof was equal to or more than 11 nm; the values are close to the values of a polycrystalline silicon film formed by crystallizing amorphous silicon having a thickness of about 60 nm with an excimer laser. The present inventors have already found that, when using such a polycrystalline silicon film, the thickness of a practical gate insulating layer is larger than that of the polycrystalline silicon film. Therefore, even when the silicon layer is irradiated, it is difficult to form a gate insulating layer having a thickness of 10 nm or less on the surface of the silicon layer. Accordingly, it is difficult to manufacture a high-performance transistor which utilizes characteristics of thinned single crystal silicon.

On the other hand, in the silicon layer after the laser beam irradiation, Ra was decreased to about 2 nm and RMS was decreased to about 2.5 to 3 nm. Therefore, by thinning the silicon layer having such planarity, a high-performance transistor which utilizes characteristics of a thinned single-crystal-silicon layer can be manufactured.

This embodiment can be combined with any of Embodiment Modes 1 to 5 and Embodiments 1 and 2 as appropriate.

### Embodiment 4

In this embodiment, the SOI substrate of Embodiment Mode 1 was inspected from a different point of view from Embodiment 3. Specifically, inspection of width of a concave portion and width of a convex portion was performed as part of evaluation of smoothness of surface roughness. Samples thereof were the same as those in Embodiment 3; therefore, specific description thereof is omitted. Further, measurement of the samples was performed with AFM like Embodiment 3.

In an obtained surface-observation image, 10 cross sections (each width in the horizontal direction: 10 μm) were selected randomly and an average width of each of a concave portion and a convex portion was calculated. Here, the calculation of width of the concave portion and the convex portion were performed using an average height. That is, an intersection between a cross-section profile with AFM and a reference line indicating the average height were each considered as an end of each concave or convex portion, and the width in the horizontal direction between the intersections which are next to each other were measured. Note that, as the above-described average height, an average height of heights at all the measurement points (512×512 points) in a 10 μm×10 μm region including the 10 cross sections of the measurement was used.

Note that the special resolution of the above-described AFM image was 19.5 nm (10 μm/512 points); and, although there was the case where the width of the concave or convex portion is the above-described minimum value due to nose in the measurement or the like, the average width of each of the concave and convex portions was calculated without excluding data of the case.

The above-described inspection results are shown in Table 2. Note that, for comparison, results of the same measurement performed on a surface of polycrystalline silicon and results of the same measurement performed on a surface of a silicon layer of an SOI substrate formed using so-called Smart-Cut were also shown.

### (Table 2)

From the above-described results, in the single crystal silicon of this embodiment, the average width of the concave portion was 97.5 nm and the average width of the convex portion was 99.8 nm; therefore, it can be said that the width of each of the concave and convex portions is in the range of about 60 to 120 nm. From the comparison with the silicon formed by Smart-Cut and the polycrystalline silicon, the width of each of the concave and convex portions may be greater than or equal to 50 nm and less than or equal to 140 nm as well. Note that a width of the concave or convex portion of about 100 nm which is very large in view of the fact that Ra was as small as several nanometers indicates that the surface becomes very smooth by the laser beam irradiation. This is because the width of the concave or convex portion is decreased when the roughness curvature is small (i.e., when the concave or convex portion is precipitous).

Note that the average value of the concave or convex portion was as small as less than 50 nm in the case of Smart-Cut; it can be considered that this is because the surface roughness itself became very small by a polishing treatment of the surface. On the other hand, in the polycrystalline silicon, the width of each of the concave and convex portions was as large as 140 nm or more; this did not result from the smoothness of the surface but resulted from that the surface roughness itself was large. In this sense, it can also be said that the surface smoothness can be expressed first by combining parameter having a meaning of perpendicular direction such as Ra and parameter having a meaning of horizontal direction such as width of the concave or convex portion.

This embodiment can be combined with any of Embodiment Modes 1 to 5 and Embodiments 1 to 3 as appropriate.

This application is based on Japanese Patent Application serial no. 2007-240219 filed in Japan Patent Office on 14 Sep. 2007, the entire contents of which are hereby incorporated by reference.

1. A semiconductor device comprising:
an insulating layer over an insulating substrate;
a bonding layer over the insulating layer; and
a single-crystal semiconductor layer over the bonding layer, wherein an arithmetic-mean roughness of a roughness shape in an upper surface of the single-crystal semiconductor layer is greater than or equal to 1 nm and less than or equal to 7 nm.

2. The semiconductor device according to claim 1, wherein the insulating layer includes a silicon oxynitride film or a silicon nitride oxide film.

3. The semiconductor device according to claim 1, wherein the single-crystal semiconductor layer has a (100) plane as a main surface.

4. The semiconductor device according to claim 1, wherein the single-crystal semiconductor layer has a (110) plane as a main surface.

5. The semiconductor device according to claim 1,
wherein an average value of a width of each concave or convex portion in the above-described roughness shape is greater than or equal to 60 nm and less than or equal to 120 nm, and
wherein the width of each concave or convex portion is measured with an average height.

6. A semiconductor device comprising:
an insulating layer over an insulating substrate;
a bonding layer over the insulating layer; and
a single-crystal semiconductor layer over the bonding layer,
wherein a root-mean-square roughness of a roughness shape in an upper surface of the single-crystal semiconductor layer is greater than or equal to 1 nm and less than or equal to 10 nm.

7. The semiconductor device according to claim 6, wherein the insulating layer includes a silicon oxynitride film or a silicon nitride oxide film.

8. The semiconductor device according to claim 6, wherein the single-crystal semiconductor layer has a (100) plane as a main surface.

9. The semiconductor device according to claim 6, wherein the single-crystal semiconductor layer has a (110) plane as a main surface.

10. The semiconductor device according to claim 6,
wherein an average value of a width of each concave or convex portion in the above-described roughness shape is greater than or equal to 60 nm and less than or equal to 120 nm, and
wherein the width of each concave or convex portion is measured with an average height.

11. A semiconductor device comprising:
an insulating layer over an insulating substrate;
a bonding layer over the insulating layer; and
a single-crystal semiconductor layer over the bonding layer,
wherein a maximum difference in height of a roughness shape in an upper surface of the single-crystal semiconductor layer is greater than or equal to 5 nm and less than or equal to 250 nm.

12. The semiconductor device according to claim 11, wherein the insulating layer includes a silicon oxynitride film or a silicon nitride oxide film.

13. The semiconductor device according to claim 11, wherein the single-crystal semiconductor layer has a (100) plane as a main surface.

14. The semiconductor device according to claim 11, wherein the single-crystal semiconductor layer has a (110) plane as a main surface.

15. The semiconductor device according to claim 11,
wherein an average value of a width of each concave or convex portion in the above-described roughness shape is greater than or equal to 60 nm and less than or equal to 120 nm, and
wherein the width of each concave or convex portion is measured with an average height.

16. A semiconductor device comprising:
a substrate with an allowable temperature limit of 700° C. or less;
an insulating layer over the substrate;
a bonding layer over the insulating layer; and
a single-crystal semiconductor layer over the bonding layer,
wherein an arithmetic-mean roughness of a roughness shape in an upper surface of the single-crystal semiconductor layer is greater than or equal to 1 nm and less than or equal to 7 nm.

17. The semiconductor device according to claim 16, wherein the substrate is a glass substrate including any of aluminosilicate glass, aluminoborosilicate glass, or bariumborosilicate glass.

18. The semiconductor device according to claim 16, wherein the insulating layer includes a silicon oxynitride film or a silicon nitride oxide film.

19. The semiconductor device according to claim 16, wherein the single-crystal semiconductor layer has a (100) plane as a main surface.

20. The semiconductor device according to claim 16, wherein the single-crystal semiconductor layer has a (110) plane as a main surface.

21. The semiconductor device according to claim 16,
wherein an average value of a width of each concave or convex portion in the above-described roughness shape is greater than or equal to 60 nm and less than or equal to 120 nm, and
wherein the width of each concave or convex portion is measured with an average height.

22. A semiconductor device comprising:
a substrate with an allowable temperature limit of 700° C. or less;
an insulating layer over the substrate;
a bonding layer over the insulating layer; and
a single-crystal semiconductor layer over the bonding layer,
wherein a root-mean-square roughness of a roughness shape in an upper surface of the single-crystal semiconductor layer is greater than or equal to 1 nm and less than or equal to 10 nm.

23. The semiconductor device according to claim 22, wherein the substrate is a glass substrate including any of aluminosilicate glass, aluminoborosilicate glass, or bariumborosilicate glass.

24. The semiconductor device according to claim 22, wherein the insulating layer includes a silicon oxynitride film or a silicon nitride oxide film.

25. The semiconductor device according to claim 22, wherein the single-crystal semiconductor layer has a (100) plane as a main surface.

26. The semiconductor device according to claim 22, wherein the single-crystal semiconductor layer has a (110) plane as a main surface.

27. The semiconductor device according to claim 22,
wherein an average value of a width of each concave or convex portion in the above-described roughness shape is greater than or equal to 60 nm and less than or equal to 120 nm, and
wherein the width of each concave or convex portion is measured with an average height.

28. A semiconductor device comprising:
a substrate with an allowable temperature limit of 700° C. or less;
an insulating layer over the substrate;
a bonding layer over the insulating layer; and
a single-crystal semiconductor layer over the bonding layer,
wherein a maximum difference in height of a roughness shape in an upper surface of the single-crystal semiconductor layer is greater than or equal to 5 nm and less than or equal to 250 nm.

29. The semiconductor device according to claim 28, wherein the substrate is a glass substrate including any of aluminosilicate glass, aluminoborosilicate glass, or bariumborosilicate glass.

30. The semiconductor device according to claim 28, wherein the insulating layer includes a silicon oxynitride film or a silicon nitride oxide film.

31. The semiconductor device according to claim 28, wherein the single-crystal semiconductor layer has a (100) plane as a main surface.

32. The semiconductor device according to claim 28, wherein the single-crystal semiconductor layer has a (110) plane as a main surface.

33. The semiconductor device according to claim 28,
wherein an average value of a width of each concave or convex portion in the above-described roughness shape is greater than or equal to 60 nm and less than or equal to 120 nm, and
wherein the width of each concave or convex portion is measured with an average height.

34. An electronic appliance using the semiconductor device according to claim 1.

35. An electronic appliance using the semiconductor device according to claim 6.

36. An electronic appliance using the semiconductor device according to claim 11.

37. An electronic appliance using the semiconductor device according to claim 16.

38. An electronic appliance using the semiconductor device according to claim 22.

39. An electronic appliance using the semiconductor device according to claim 28.
